(19) United States
(12) Patent Application Publication
(10) Pub. No.: US 2025/0201700 A1
(43) Pub. Date: Jun. 19, 2025

(54) INTEGRATED CIRCUIT DEVICE

(71) Applicant: Samsung Electronics Co., Ltd., Suwon-si (KR)

(72) Inventors: Donggon Yoo, Suwon-si (KR); Sukhoon Kim, Suwon-si (KR); Byounghoon Lee, Suwon-si (KR)

(21) Appl. No.: 18/960,744

(22) Filed: Nov. 26, 2024

(30) Foreign Application Priority Data
Dec. 13, 2023 (KR) 10-2023-0181160

(51) Int. Cl. H01L 23/522; H01L 23/532; H01L 27/088; H01L 29/06; H01L 29/423; H01L 29/775; H01L 29/786

(52) U.S. Cl. CPC H01L 23/5226; H01L 23/53252; H01L 23/53266; H10D 84/83; H10D 30/43; H10D 30/6735; H10D 30/6757; H10D 62/121

(57) ABSTRACT

Provided is an integrated circuit device. The integrated circuit device includes a substrate, a cell transistor disposed on a substrate, a contact electrically connected to the cell transistor, a conductive via disposed on the contact and including a via conductive layer disposed on a top surface of the contact and a via skin layer covering a top surface of the via conductive layer, a first interlayer insulation layer surrounding a portion of a sidewall of the conductive via, and a wiring line disposed on the interlayer insulation layer, extending in a first horizontal direction, contacting a top surface of the conductive via, and including a bottom barrier line and a main conductive line disposed on the bottom barrier line.

### CROSS-REFERENCE TO RELATED APPLICATION

This application is based on and claims priority under 35 U.S.C. § 119 to Korean Patent Application No. 10-2023-0181160, filed on Dec. 13, 2023, in the Korean Intellectual Property Office, the disclosure of which is incorporated by reference herein in its entirety.

### BACKGROUND

The inventive concept relates to an integrated circuit device, and more particularly, to an integrated circuit device including a field-effect transistor.

Due to the development of the electronic technology, the demand for high integration of integrated circuit devices is increasing, and accordingly, downscaling is in progress. As integrated circuit devices are downscaled, the development of integrated circuit devices that include contacts and wires that may exhibit excellent electrical connection characteristics even within a relatively small device area is preferred.

### SUMMARY

The inventive concept provides an integrated circuit device including contacts and wires with excellent electrical connection characteristics within a relatively small device area.

According to an aspect of the inventive concept, there is provided an integrated circuit device including a substrate, a cell transistor disposed on the substrate, a contact electrically connected to the cell transistor, a conductive via disposed on the contact and including a via conductive layer disposed on a top surface of the contact and a via skin layer covering a top surface of the via conductive layer, an interlayer insulation layer surrounding a portion of a sidewall of the conductive via, and a wiring line disposed on the interlayer insulation layer, extending in a first horizontal direction, contacting a top surface of the conductive via, and including a bottom barrier line and a main conductive line disposed on the bottom barrier line.

According to another aspect of the inventive concept, there is provided an integrated circuit device including a substrate, a cell transistor disposed on the substrate, a contact electrically connected to the cell transistor, a first interlayer insulation layer disposed on the contact and including a via hole, a conductive via disposed in the via hole, electrically connected to the contact, and including a via conductive layer disposed on a top surface of the contact and a via skin layer covering a top surface of the via conductive layer, a wiring line disposed on the first interlayer insulation layer, extending in a first horizontal direction, contacting a top surface of the conductive via, and including a bottom barrier line and a main conductive line disposed on the bottom barrier line, and a second interlayer insulation layer disposed on the first interlayer insulation layer and disposed on sidewalls of the main conductive line and sidewalls of the bottom barrier line.

According to another aspect of the inventive concept, there is provided an integrated circuit device including a substrate, an active region disposed on the substrate and including a plurality of nano-sheets spaced apart from one another in a vertical direction perpendicular to a top surface of the substrate, a gate line surrounding the plurality of nano-sheets on the substrate and extending in a first horizontal direction, a source/drain region disposed on opposing sides of the gate line on the substrate, a contact disposed on the source/drain region, a conductive via disposed on the contact and including a via conductive layer disposed on a top surface of the first contact and a via skin layer covering a top surface of the via conductive layer, a first interlayer insulation layer surrounding a sidewall of the conductive via, a wiring line disposed on the first interlayer insulation layer, extending in a second horizontal line intersecting the first horizontal direction, contacting a top surface of the conductive via, and including a bottom barrier line and a main conductive line disposed on the bottom barrier line, and a second interlayer insulation layer disposed on the first interlayer insulation layer and surrounding sidewalls of the wiring line.

### BRIEF DESCRIPTION OF THE DRAWINGS

Embodiments of the inventive concept will be more clearly understood from the following detailed description taken in conjunction with the accompanying drawings in which:

FIG. 1 is a schematic layout diagram showing an integrated circuit device according to embodiments;

FIG. 2 is a cross-sectional view taken along a line A1-A1′ of FIG. 1;

FIG. 3 is a cross-sectional view taken along a line B1-B1′ of FIG. 1;

FIG. 4 is a cross-sectional view taken along a line B2-B2′ of FIG. 1;

FIG. 5 is a cross-sectional view taken along a line B3-B3′ of FIG. 1;

FIG. 6 is an enlarged view of a portion CX1 of FIG. 3;

FIGS. 7 and 8 are cross-sectional views of an integrated circuit device according to embodiments; and

FIGS. 9A, 9B, 9C, 10A, 10B, 10C, 11A, 11B, 11C, 12A, 12B, 12C, 12D, 13A, 13B, 13C, 13D, 14A, 14B, 14C, 15A, 15B, 15C, 15D, 16A, 16B, 16C, 17A, 17B, 17C, 17D, 18A, 18B, 18C, 18D, 19A, 19B, 19C, 19D, 20A, 20B, 20C, 20D, 21A, 21B, 21C, and 21D are cross-sectional views showing a state of an integrated circuit device during a method of manufacturing an integrated circuit device, according to embodiments.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the following description ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

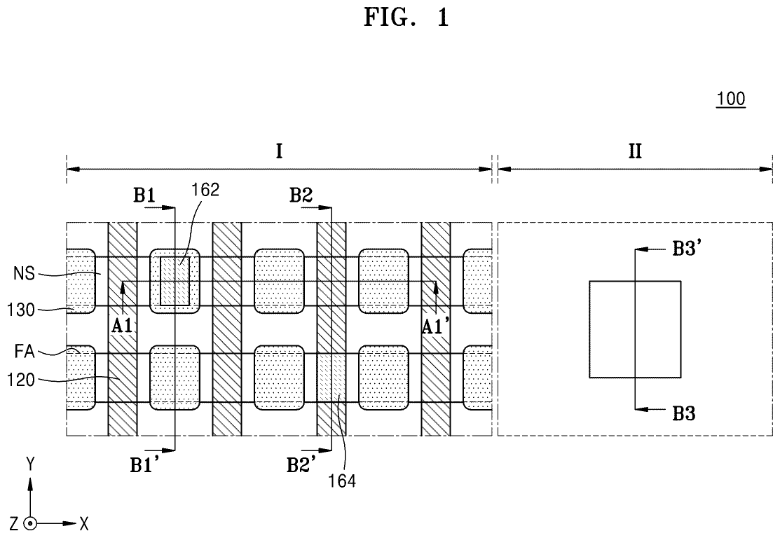

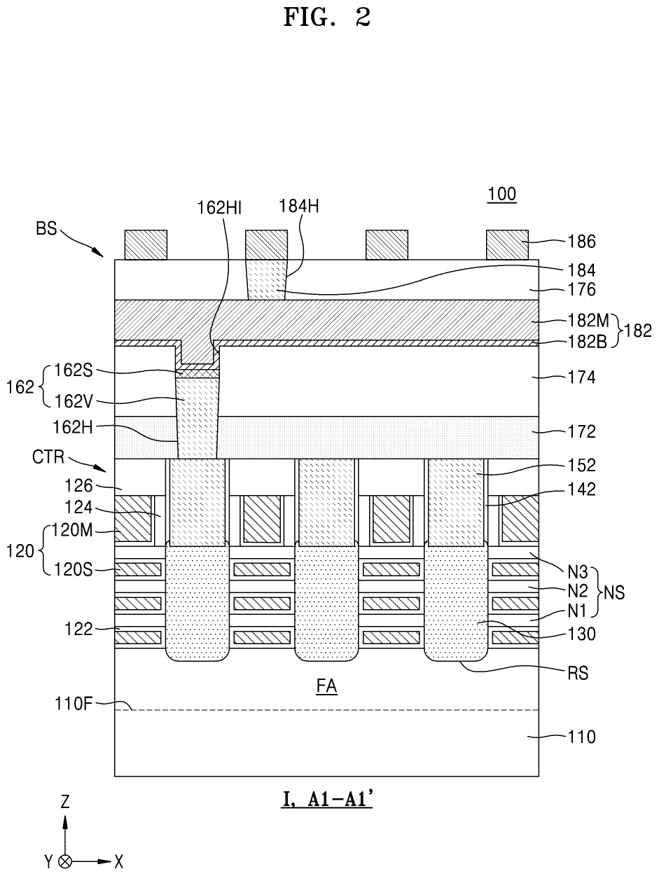

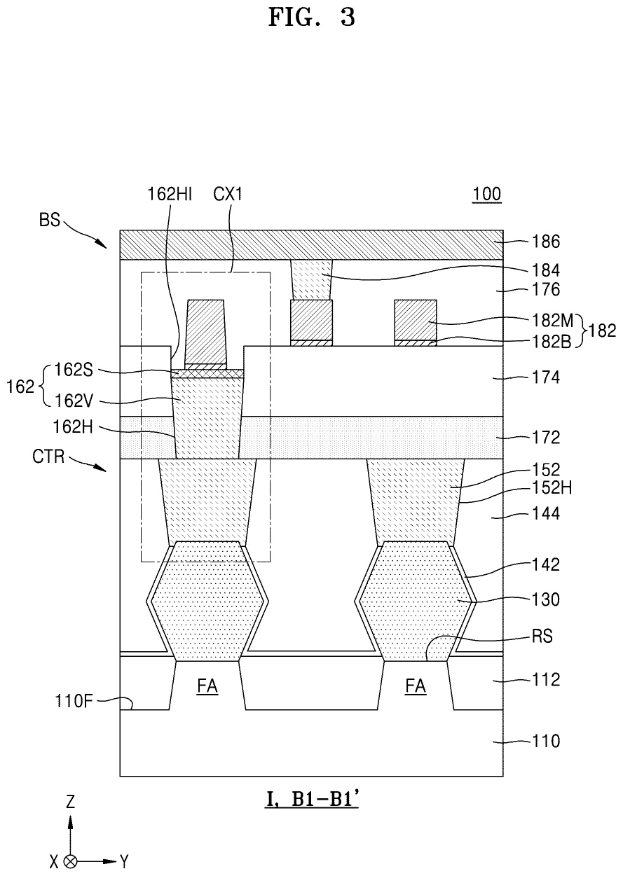

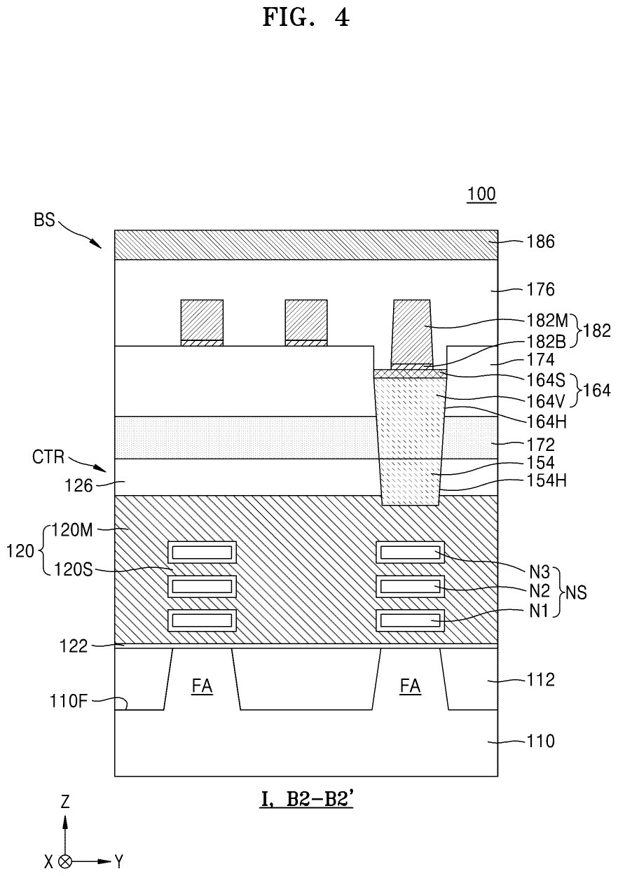

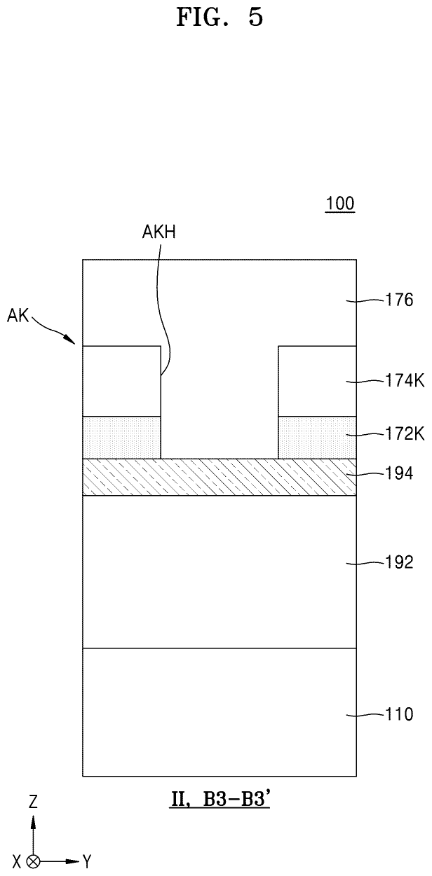

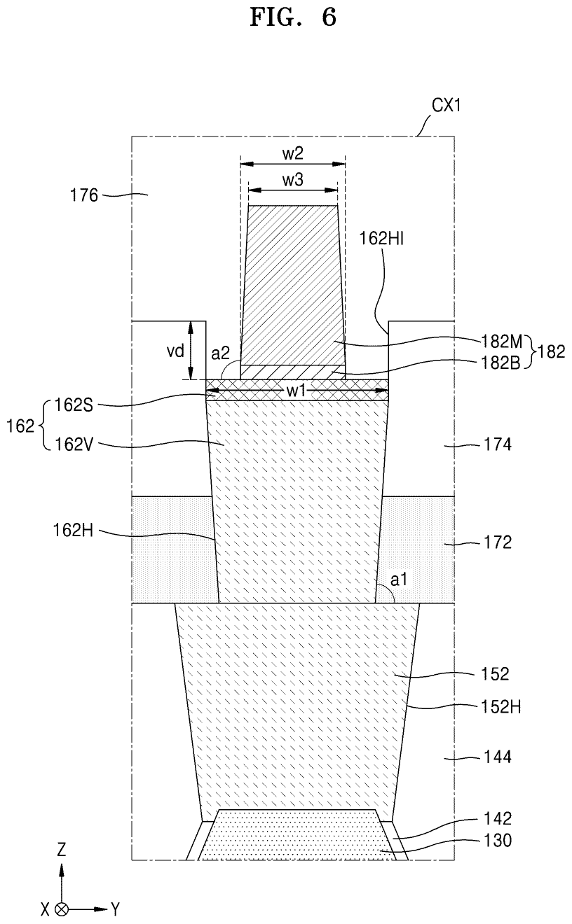

FIG. 1 is a schematic layout diagram showing an integrated circuit device 100 according to embodiments. FIG. 2 is a cross-sectional view taken along a line A1-A1′ of FIG. 1. FIG. 3 is a cross-sectional view taken along a line B1-B1′ of FIG. 1. FIG. 4 is a cross-sectional view taken along a line B2-B2′ of FIG. 1. FIG. 5 is a cross-sectional view taken along a line B3-B3′ of FIG. 1. FIG. 6 is an enlarged view of a portion CX1 of FIG. 3.

Referring to FIGS. 1 to 6, a substrate 110 may include a cell region I and a scribe lane region II. The cell region I may be a region where a cell transistor CTR and various types of peripheral circuits configured to drive the cell transistor CTR are formed on the substrate. The cell transistor CTR may constitute various types of logic cells included in a logic circuit. The scribe lane region II may be a region on at least one side of the cell region I and may be a region where an alignment key pattern AK is disposed.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”. Additionally, although a single element may be described, it will be understood that the description of the single element is applicable to a plurality of the single element, unless the context clearly indicates otherwise. Furthermore, relationships between involving a plurality of items may be a one-to-one relationship, a one-to-many relationship, a many-to-many relationship, or a many-to-one relationship, unless the context clearly indicates a specific relationship of each item in the plurality.

In embodiments exemplified in FIGS. 1 to 6, the integrated circuit device 100 may constitute a logic cell including a multi-bridge channel FET (MBCFET) device. However, the inventive concept is not limited thereto, and the integrated circuit device 100 may include a planar FET device, a gate-all-around type FET device, a finFET device, a FET device based on a 2-dimensional material like a MoS₂ semiconductor gate electrode, etc.

According to embodiments, the substrate 110 may be formed of and/or include a group IV semiconductor such as Si or Ge, a group IV-IV compound semiconductor such as SiGe or SiC, or a group III-V compound semiconductor such as GaAs, InAs, or InP. A plurality of fin-type active regions FA may protrude from a first surface 110F of the substrate 110 and extend in a first horizontal direction X.

A device isolation layer 112 may be disposed on the first surface 110F of the substrate 110 to cover lower portions of sidewalls of the fin-type active region FA (see FIG. 3). The device isolation layer 112 may fill the interior of a device isolation trench 112T extending from the first surface 110F of the substrate 110 towards the top of the device isolation trench 112T and may have, for example, a double-layer structure including an interface layer (not shown) and a filling insulation layer (not shown).

According to embodiments, a plurality of semiconductor patterns NS may be arranged above the fin-type active region FA to be spaced apart from one another in a vertical direction Z. The plurality of semiconductor patterns NS may each be formed of and/or include a group IV semiconductor such as Si or Ge, a group IV-IV compound semiconductor such as SiGe or SiC, or a group III-V compound semiconductor such as GaAs, InAs, or InP.

In some examples, each semiconductor pattern of the plurality of semiconductor patterns NS may have a relatively large width in a second horizontal direction Y relative to a width in the first horizontal direction X, may have a relatively small thickness in the vertical direction Z relative to the width in second horizontal direction Y, and may have the shape of a nano-sheet. For example, as shown in FIG. 2, the plurality of semiconductor patterns NS may include a first nano-sheet N1, a second nano-sheet N2, and a third nano-sheet N3 arranged to be spaced apart from one another in the vertical direction Z on the fin-type active region FA. However, the number of semiconductor patterns NS is not limited to that shown in FIG. 2. The plurality of semiconductor patterns NS may each function as a channel region for a transistor.

According to embodiments, each semiconductor pattern NS of the plurality of semiconductor patterns NS may have a width in the second horizontal direction Y ranging from about 5 nm to about 100 nm, and each semiconductor pattern NS of the plurality of semiconductor patterns NS may have a width in the vertical direction Z ranging from about 1 nm to about 10 nm. However, the inventive concept is not limited thereto. According to some embodiments, at least one semiconductor pattern NS from among the plurality of semiconductor patterns NS may have a thickness in the vertical direction Z different from that of the remaining semiconductor patterns NS.

A plurality of gate lines 120 may extend in the second horizontal direction Y to surround the plurality of semiconductor patterns NS on the fin-type active region FA (see FIG. 4) and may be arranged in the first horizontal direction X to be spaced apart from one another at regular gate intervals.

According to embodiments, the plurality of gate lines 120 may be formed of and/or include a doped polysilicon, a metal, a conductive metal nitride, a conductive metal carbide, a conductive metal silicide, or a combination thereof. For example, the plurality of gate lines 120 may be formed of and/or include Al, Cu, Ti, Ta, W, Mo, TaN, NiSi, CoSi, TiN, WN, TiAl, TiAlN, TaCN, TaC, TaSiN, or combinations thereof. However, the inventive concept is not limited thereto. According to embodiments, the plurality of gate lines 120 may include a work function metal-containing layer (not shown) and a gap-fill metal layer (not shown). The work function metal-containing layer may be formed of and/or include at least one metal selected from among Ti, W, Ru, Nb, Mo, Hf, Ni, Co, Pt, Yb, Tb, Dy, Er, and Pd. The gap-fill metal layer may be formed of and/or include a W layer or an Al layer. According to embodiments, the plurality of gate lines 120 may have a stacked structure of TiAlC/TiN/W, a stacked structure of TiN/TaN/TiAlC/TiN/W, or a stacked structure of TiN/TaN/TiN/TiAlC/TiN/W, where stacked structure in this example indicates that the items are stacked on top of one another in the given order. However, the inventive concept is not limited thereto.

According to embodiments, the plurality of gate lines 120 may each include a main gate portion 120M covering the uppermost semiconductor pattern NS and a sub-gate portion 120S disposed between two semiconductor patterns NS adjacent to each other. For example, the main gate portion 120M may cover the top surface of the third nano-sheet N3, and the sub-gate portion 120S may be located between the fin-type active region FA and the first nano-sheet N1, between the first nano-sheet N1 and the second nano-sheet N2, and between the second nano-sheet N2 and the third nano-sheet N3.

A gate insulation layer 122 may be disposed between the plurality of gate lines 120 and the plurality of semiconductor patterns NS. For example, the gate insulation layer 122 may be disposed between the main gate portion 120M of each of the plurality of gate lines 120 and the uppermost semiconductor pattern NS, between the sub-gate portion 120S of each of the plurality of gate lines 120 and each of the semiconductor patterns NS, and between the sub-gate portion 120S and the top surface of the fin-type active region FA.

According to embodiments, the gate insulation layer 122 may be formed of and/or include a silicon oxide film, a silicon oxynitride film, a high-k film having a higher dielectric constant than a silicon oxide film, or a combination thereof. The high-k film may be formed of and/or include a metal oxide or a metal oxynitride. For example, the high-k film that may be used as the gate insulation layer 122 may include, but is not limited to, HfO₂, HfSiO, HfSiON, HfTaO, HfTiO, HfZrO, ZrO₂, Al₂O₃, or a combination thereof.

Outer insulation spacers 124 may be arranged on sidewalls of the main gate portion 120M of each of the gate lines 120. The outer insulation spacers 124 may be arranged on opposing ends of the uppermost semiconductor pattern NS and may be arranged to be spaced apart from the gate line 120 with the gate insulation layer 122 therebetween. According to embodiments, the outer insulation spacers 124 may be formed of and/or include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof.

A plurality of recesses RS extending into the fin-type active region FA may be formed at opposing sides of the plurality of gate lines 120, and a plurality of source/drain regions 130 may be formed inside the plurality of recesses RS. The plurality of source/drain regions 130 are formed inside the plurality of recesses RS, respectively, and may be connected to opposing ends of the plurality of semiconductor patterns NS. According to embodiments, the plurality of source/drain regions 130 may be formed of and/or include a doped SiGe layer, a doped Ge layer, a doped SiC layer, or a doped InGaAs layer, but the inventive concept is not limited thereto.

According to some embodiments, an inner spacer may optionally be disposed between the sub-gate portion 120S of the gate line 120 and the source/drain region 130. Inner spacers may be arranged between two semiconductor patterns NS that are adjacent to each other from among the plurality of semiconductor patterns NS and between the source/drain region 130 and the sub-gate portion 120S of the gate line 120 facing the source/drain region 130.

A gate capping layer 126 may be disposed on the plurality of gate lines 120 and the outer insulation spacers 124, and a passivation layer 142 covering the source/drain region 130 between the plurality of gate lines 120 and an inter-gate insulation layer 144 may be formed. According to embodiments, the passivation layer 142 and the inter-gate insulation layer 144 may be formed of and/or include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof.

A first contact 152 may be disposed in a first contact hole 152H penetrating through the passivation layer 142 and the inter-gate insulation layer 144. The first contact 152 may be disposed on the top surface of the source/drain region 130 that is exposed at the bottom of the first contact hole 152H. According to embodiments, the top surface of the first contact 152 may be disposed on the same plane as the top surface of the gate capping layer 126.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

According to embodiments, the first contact 152 may be formed of and/or include at least one of Mo, MON, Co, CON, W, WN, Ru, RuN, Ti, or TiN. According to some embodiments, a metal silicide film including tungsten silicide, cobalt silicide, nickel silicide, etc. may be additionally provided between the source/drain region 130 and the first contact 152.

A second contact 154 may be disposed in a second contact hole 154H penetrating through the gate capping layer 126 and that exposes the top surface of the gate line 120. The second contact 154 may be disposed on the top surface of the gate line 120 that is exposed at the bottom of the second contact hole 154H. According to embodiments, the top surface of the second contact 154 may be disposed on the same plane as the top surface of the gate capping layer 126. According to embodiments, the second contact 154 may be formed of and/or include at least one of Mo, MON, Co, CON, W, WN, Ru, RuN, Ti, or TiN.

A back-end-of-line (BEOL) structure BS may be disposed on the gate capping layer 126 and the inter-gate insulation layer 144. The BEOL structure BS may include a first conductive via 162, a second conductive via 164, a lower insulation layer 172, a first interlayer insulation layer 174, a second interlayer insulation layer 176, first wiring lines 182, an upper via 184, and second wiring lines 186.

The lower insulation layer 172 may be disposed on the gate capping layer 126 and the inter-gate insulation layer 144. The lower insulation layer 172 may be formed of and/or include silicon nitride. The first interlayer insulation layer 174 may be disposed on the lower insulation layer 172. The first interlayer insulation layer 174 may be formed of and/or include silicon oxide or a low-k material.

A first via hole 162H may penetrate through the lower insulation layer 172 and the first interlayer insulation layer 174 to expose the top surface of the first contact 152. The first conductive via 162 may be disposed in the first via hole 162H. For example, the sidewall of the first conductive via 162 may be surrounded by the lower insulation layer 172 and the first interlayer insulation layer 174.

The first conductive via 162 may include a first via conductive layer 162V and a first via skin layer 162S disposed on the top surface of the first via conductive layer 162V. The first conductive via 162 may function as a connection component for electrical connection to the source/drain region 130 and/or the substrate 110 (e.g., may provide an electrical connection between components).

According to embodiments, the first via conductive layer 162V may fill the lower portion of the first via hole 162H and may contact the top surface of the first contact 152. The first via skin layer 162S may be formed to a relatively thin thickness on the entire top surface of the first via conductive layer 162V. For example, the first via skin layer 162S may have a thickness in the range of from about 0.5 nm to about 5 nm.

According to embodiments, the first via conductive layer 162V may be formed of and or include at least one of molybdenum, ruthenium, or tungsten, and the first via skin layer 162S may be formed of and/or include tungsten or ruthenium. According to some embodiments, the first via conductive layer 162V may be formed of and/or include molybdenum, and the first via skin layer 162S may be formed of and/or include tungsten.

According to embodiments, the top width of the first via hole 162H may be greater than the bottom width of the first via hole 162H, and, for example, the sidewall of the first via hole 162H may have an inclination angle a1 from about 70 degrees to about 90 degrees with respect to the top surface of the substrate 110. According to embodiments, the first via hole 162H may be formed through an etching process that removes a portion of the first interlayer insulation layer 174 and a portion of the second lower insulation layer 172, and, during the etching process, the upper portion of the first via hole 162H may be exposed to the etching atmosphere of the etching process for a longer period of time relative to the lower portion of the first via hole 162H. As a result, the sidewall of the first via hole 162H may be inclined, such that the top width of the first via hole 162H is greater than the bottom width of the first via hole 162H.

According to embodiments, the first conductive via 162 may be disposed to fill at least a portion of the first via hole 162H, and may not fill the upper portion of the first via hole 162H (e.g., the remaining portion of the first via hole 162H). The top surface of the first conductive via 162 (i.e., the top surface of the first via skin layer 162S) may be disposed at a vertical level that is lower than a vertical level of the top surface of the first interlayer insulation layer 174, and the portion of the first via hole 162H between the top surface of the first interlayer insulation layer 174 and the top surface of the first conductive via 162 may be an inlet portion 162HI of the first via hole 162H. Thus, the inlet portion 162HI of the first via hole 162H may not be filled by first conductive via 162. For example, the first via skin layer 162S may cover only the entire top surface of the first via conductive layer 162V and may not extend vertically onto the upper portion of the sidewall of the first via hole 162H. Therefore, the inlet portion 162HI of the first via hole 162H may not be covered by the first via skin layer 162S. According to embodiments, a distance vd in the vertical direction between the top surface of the first conductive via 162 (i.e., the top surface of the first via skin layer 162S) and the top surface of the first interlayer insulation layer 174 may be greater than 0 nm and smaller than 10 nm.

A second via hole 164H may penetrate through the lower insulation layer 172 and the first interlayer insulation layer 174 to expose the top surface of the second contact 154. The second conductive via 164 may be disposed within the second via hole 164H. The second conductive via 164 may include a second via conductive layer 164V and a second via skin layer 164S disposed on the top surface of the second via conductive layer 164V. The second conductive via 164 may function as a connection component for electrical connection to the plurality of gate lines 120.

According to embodiments, the second via conductive layer 164V may fill a lower portion of the second via hole 164H and may contact the top surface of the second contact 154. The second via skin layer 164S may be formed to a relatively thin thickness on the entire top surface of the second via conductive layer 164V. According to embodiments, the second via conductive layer 164V may be formed of and/or include at least one of molybdenum, ruthenium, and tungsten, and the second via skin layer 164S may be formed of and/or include tungsten or ruthenium. According to some embodiments, the second via conductive layer 164V may be formed of and/or include molybdenum, and the second via skin layer 164S may be formed of and/or include tungsten.

The second via conductive layer 164V and the second via skin layer 164S may be formed of and/or include the same materials as the first via conductive layer 162V and the first via skin layer 162S, respectively, and may be formed through the same process as the first via conductive layer 162V and the first via skin layer 162S, respectively. Hereinafter, descriptions of the second conductive via 164 similar to those of the first conductive via 162 and which would be redundant may be omitted, and, unless stated otherwise, the technical features described for the first conductive via 162 may be similarly applied to the second conductive via 164.

The first wiring lines 182 may be arranged on the first interlayer insulation layer 174. The first wiring lines 182 may be spaced apart from each other at regular intervals in the second horizontal direction Y and extend in the first horizontal direction X. At least a portion of a first wiring line 182 may be disposed in the first via hole 162H and electrically connected to the first conductive via 162. At least a portion of another first wiring line 182 may be disposed in the second via hole 164H and electrically connected to the second conductive via 164.

According to embodiments, the first wiring line 182 may include a bottom barrier line 182B and a main conductive line 182M. The bottom barrier line 182B may be disposed on the first interlayer insulation layer 174 and extend in the first horizontal direction X. According to embodiments, bottom barrier line 182B may have a thickness in the range of from about 0.5 nm to about 5 nm. The main conductive line 182M may be disposed on the bottom barrier line 182B and extend in the first horizontal direction X.

According to embodiments, the bottom barrier line 182B may be formed of and/or include molybdenum and the main conductive line 182M may be formed of and/or include at least one of tungsten, ruthenium, or molybdenum. According to some embodiments, the bottom barrier line 182B may be formed of and/or include molybdenum and the main conductive line 182M may be formed of and/or include tungsten.

According to embodiments, the first wiring line 182 may be formed by sequentially forming the bottom barrier line 182B and the main conductive line 182M on the first interlayer insulation layer 174 and patterning the main conductive line 182M and the bottom barrier line 182B thereafter. During the patterning process, the upper portion of the first wiring line 182 may be exposed to the etching atmosphere of the patterning process for a longer period of time, and thus the sidewall of the first wiring line 182 may have an inclination angle a2 from about 90 degrees to about 110 degrees with respect to the top surface of the substrate 110.

According to embodiments, the top surface of the first conductive via 162 (e.g., the top surface of the first via skin layer 162S) may have a first width w1 in the second horizontal direction Y, and the bottom surface of the first wiring line 182 (e.g., the bottom surface of the bottom barrier line 182B) may have a second width w2, which is smaller than the first width w1, in the second horizontal direction Y. Also, the top surface of the first wiring line 182 (e.g., the top surface of the main conductive line 182M) may have a third width w3, which is smaller than the second width w2, in the second horizontal direction Y.

Since the second width w2 of the bottom surface of the first wiring line 182 is smaller than the first width w1 of the top surface of the first conductive via 162, at least a portion of the top surface of the first conductive via 162 (i.e., the top surface of the first via skin layer 162S) may be exposed without being covered by the bottom surface of the first wiring line 182, and at least another portion of the top surface of the first conductive via 162 (i.e., the top surface of the first via skin layer 162S) may be covered by the second interlayer insulation layer 176 (e.g., the second interlayer insulation layer 176 may extend into the first hole 162H to contact a portion of the top surface of the first conductive via 162).

The sidewall of the first wiring line 182 may be surrounded by the second interlayer insulation layer 176. For example, the sidewall of the main conductive line 182M and the sidewall of the bottom barrier line 182B may be surrounded by the second interlayer insulation layer 176 and may be in contact with the second interlayer insulation layer 176.

The upper via 184 may be disposed at the top surface of the first wiring line 182. The sidewall of the upper via 184 may be covered by the second interlayer insulation layer 176. A second wiring line 186 may be disposed on the second interlayer insulation layer 176 and may contact the top surface of the upper via 184.

According to embodiments, the upper via 184 may be formed of and/or include at least one of Mo, MON, Co, CON, W, WN, Ru, RuN, Ti, or TiN. According to embodiments, the second wiring line 186 may extend in one direction, e.g., the second horizontal direction Y, on the second interlayer insulation layer 176.

The alignment key pattern AK may be disposed on the scribe lane region II of the substrate 110. The alignment key pattern AK may be disposed on a lower buried layer 192, and the alignment key pattern AK may include a first insulation layer 194, a second insulation layer 172K, and a third insulation layer 174K.

According to embodiments, the lower buried layer 192 may be formed of and/or include silicon oxide, the first insulation layer 194 may be formed of and/or include silicon nitride, the second insulation layer 172K may be formed of and/or include silicon nitride. and the third insulation layer 174K may be formed of and/or include silicon oxide. For example, the alignment key pattern AK may include an alignment hole AKH, the alignment hole AKH may penetrate through the second insulation layer 172K and the third insulation layer 174K, and the top surface of the first insulation layer 194 may be exposed at the bottom of the alignment hole AKH. The alignment hole AKH may be used as a mark pattern for maintaining alignment between the first wiring layer M1 formed in the cell region I and the first conductive via 162 or between the first wiring layer M1 and the second conductive via 164. The alignment key pattern AK may be covered by the second interlayer insulation layer 176, and, for example, the second interlayer insulation layer 176 may be disposed in the alignment hole AKH.

Generally, as the horizontal area of cell region decreases in a multi-bridge channel type field-effect transistor device, widths of a first via and a first wiring layer also need to decrease. However, for copper wires formed using a conventional damascene method, it is necessary to form an opening in an interlayer insulation layer and then sequentially form a barrier layer and a copper metal layer in the opening, and thus it is difficult to reduce the width of a wiring layer. To replace the damascene method and enable smaller widths of the first via and the first wiring layer, a method of forming a first wiring layer using an etching pattern with a metal material such as ruthenium is possible. However, the manufacturing cost of the metal material such as ruthenium is expensive and there is a problem with an increase in electrical resistance due to oxidization of the top surface of a first via from being exposed to an etching atmosphere.

However, according to the embodiments described above, on the first conductive via 162 including the first via conductive layer 162V and the first via skin layer 162S, the first wiring line 182 including the bottom barrier line 182B and the main conductive line 182M may be disposed. The main conductive line 182M may include a metal material such as tungsten that may be formed by using an etching patterning method and may prevent damage to the first interlayer insulation layer 174 during the process of patterning the bottom barrier line 182B. Also, as the first via skin layer 162S is disposed on the entire top surface of the first via conductive layer 162V, exposure of the first via conductive layer 162V to the etching atmosphere during the etching patterning process may be prevented. Therefore, even when the line width of the first wiring line 182 is reduced, an electrical connection structure with low resistance may be provided, and the integrated circuit device 100 may exhibit excellent electrical characteristics.

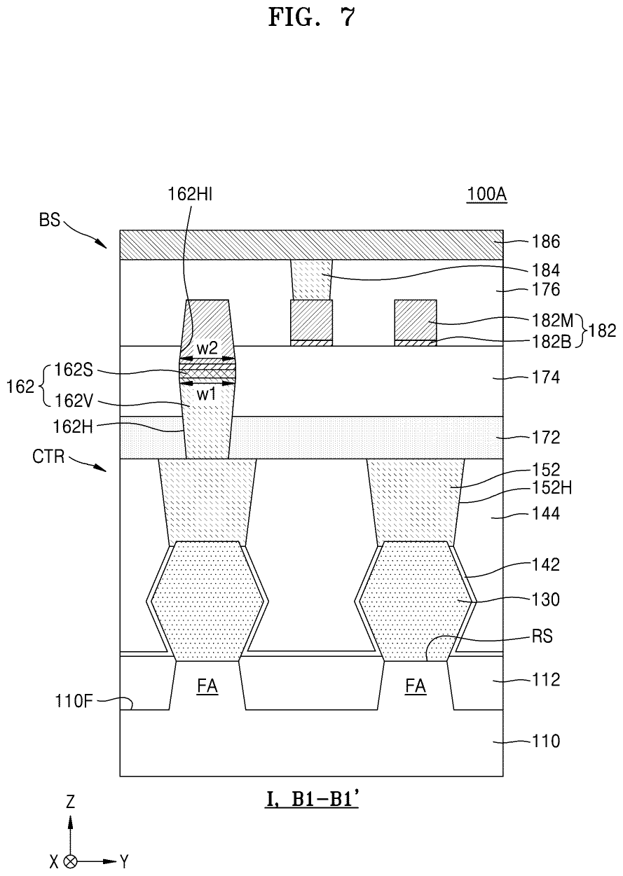

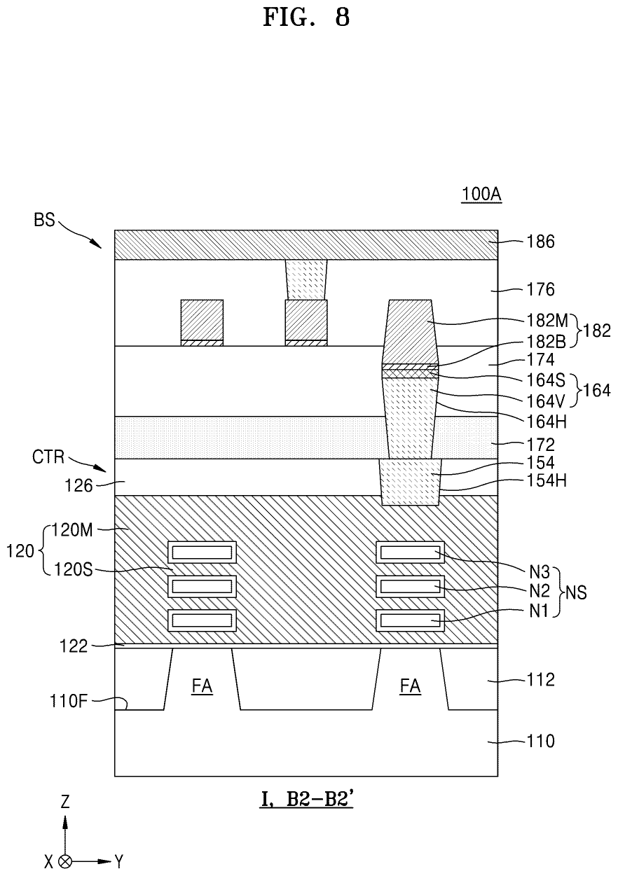

FIGS. 7 and 8 are cross-sectional views of an integrated circuit device 100A according to embodiments.

Referring to FIGS. 7 and 8, the second width w2 of the bottom surface of the first wiring line 182 may be equal to or greater than the first width w1 of the top surface of the first conductive via 162. The entire top surface of the first conductive via 162 (i.e., the top surface of the first via skin layer 162S) may be covered by the first wiring line 182. Also, the inlet portion 162HI of the first via hole 162H may be completely filled with the first wiring line 182.

According to embodiments, the main conductive line 182M of the first wiring line 182 may be formed of and/or include tungsten. The upper via 184 may be disposed on the top surface of the main conductive line 182M of the first wiring line 182, and the upper via 184 may be formed of and/or include molybdenum.

According to embodiments, when the upper via 184 is formed of and/or includes molybdenum and the upper via 184 including molybdenum is formed on the top surface of the main conductive line 182M which includes tungsten, the lattice mismatch between the crystal lattice of tungsten and the crystal lattice of molybdenum is relatively small, and thus the crystallinity of molybdenum may be excellent. Also, the upper via 184 may have a relatively low resistivity due to the excellent crystallinity of molybdenum constituting the upper via 184, and thus the resistance of the upper via 184 may be relatively low.

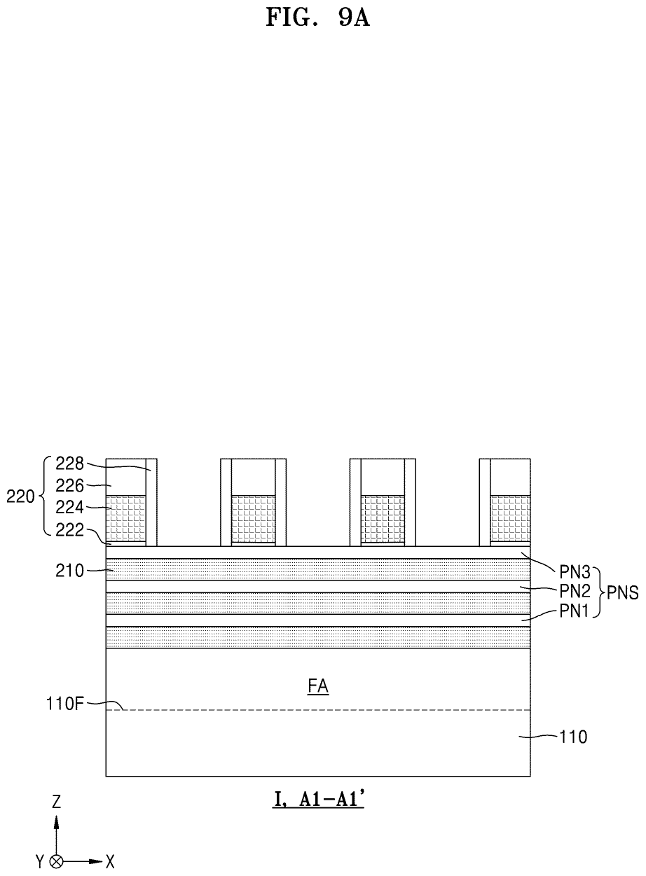

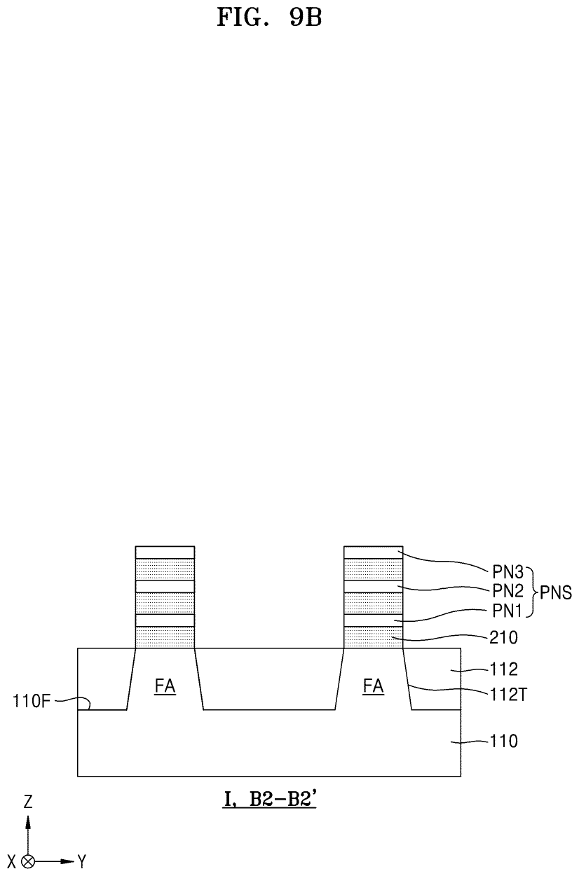

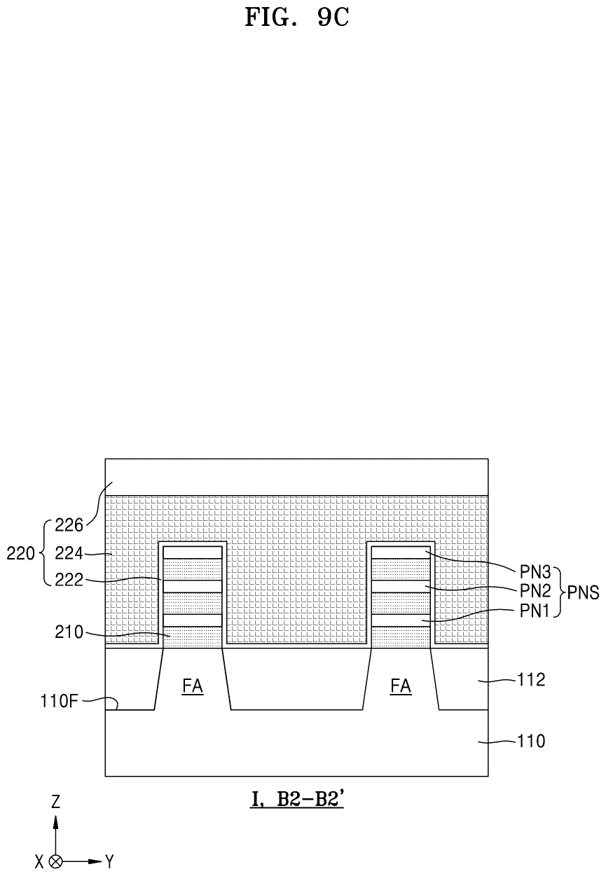

FIGS. 9A, 9B, 9C, 10A, 10B, 10C, 11A, 11B, 11C, 12A, 12B, 12C, 12D, 13A, 13B, 13C, 13D, 14A, 14B, 14C, 15A, 15B, 15C, 15D, 16A, 16B, 16C, 17A, 17B, 17C, 17D, 18A, 18B, 18C, 18D, 19A, 19B, 19C, 19D, 20A, 20B, 20C, 20D, 21A, 21B, 21C, and 21D are cross-sectional views showing states of an integrated circuit device 100 during a method of manufacturing the integrated circuit device 100, according to embodiments.

Referring to FIGS. 9A to 9C, sacrificial layers 210 and channel semiconductor layers PNS may be formed alternately and sequentially on the top surface of the substrate 110.

According to embodiments, the sacrificial layers 210 and the channel semiconductor layers PNS may be formed through an epitaxial process. According to embodiments, a sacrificial layer 210 and a channel semiconductor layer PNS may include materials having etch selectivity with respect to each other. For example, the sacrificial layer 210 and the channel semiconductor layer PNS may each be formed of and/or include a monocrystalline layer of a group IV semiconductor, a group IV-IV compound semiconductor, or a group III-V compound semiconductor, wherein the sacrificial layer 210 and the channel semiconductor layer PNS may be formed of and/or include different materials. According to embodiments, the sacrificial layer 210 may be formed of and/or include SiGe, and the channel semiconductor layer PNS may be formed of and/or include monocrystalline silicon.

According to embodiments, the epitaxial process may be a chemical vapor deposition (CVD) process such as vapor-phase epitaxy (VPE), or ultra-high vacuum chemical vapor deposition (UHV-CVD), molecular beam epitaxy, or a combination thereof. In the epitaxial process, a liquid or gaseous precursor may be used as a precursor needed for forming the sacrificial layer 210 and the channel semiconductor layer PNS.

Thereafter, after a hard mask pattern (not shown) extending to a certain length in the first direction (X direction) is formed on the uppermost channel semiconductor layer PNS, the sacrificial layer 210, the channel semiconductor layer PNS. The substrate 110 may be etched using the hard mask pattern as an etching mask. A stacked structure of the channel semiconductor layers PNS and the sacrificial layers 210 may have a line-type pattern shape extending in the first direction (X direction), and the device isolation trenches 112T may be formed between stacked line patterns of the channel semiconductor layers PNS and the sacrificial layers 210.

For example, the channel semiconductor layers PNS may include a first channel semiconductor layer PN1, a second channel semiconductor layer PN2, and a third channel semiconductor layer PN3 that are spaced apart from one another in the vertical direction Z, above the first surface 110F of the substrate 110. The sacrificial layers 210 may be provided between the top surface of the substrate 110 and the first channel semiconductor layer PN1, between the first channel semiconductor layer PN1 and the second channel semiconductor layer PN2, and between the second channel semiconductor layer PN2 and the third channel semiconductor layer PN3.

Thereafter, the inside of the device isolation trench 112T may be filled with an insulating material. After the inside of the device isolation trench 112T is filled with an insulating material, the device isolation layer 112 that fills the device isolation trench 112T may be formed by planarizing the upper portion of the insulating material. The fin-type active regions FA may be defined in the substrate 110 by the device isolation layer 112.

Thereafter, a sacrificial gate structure 220 may be formed on the stacked line patterns, which includes the channel semiconductor layers PNS and the sacrificial layers 210, and on the device isolation layer 112. The sacrificial gate structure 220 may include a sacrificial insulation layer pattern 222, a sacrificial gate line 224, a sacrificial gate capping layer 226, and a sacrificial gate spacer 228.

The sacrificial insulation layer pattern 222 extends in the second horizontal direction Y and may be conformally formed on top surfaces and sidewalls of the stacked line patterns, which include the channel semiconductor layers PNS and the sacrificial layers 210, and may be conformally formed on the top surface of the device isolation layer 112. According to embodiments, the sacrificial insulation layer pattern 222 may be formed of and/or include a material that has an etch selectivity with the sacrificial gate line 224, e.g., at least one of a thermal oxide, a silicon oxide, or a silicon nitride.

The sacrificial gate line 224 may be formed on the sacrificial insulation layer pattern 222 and may be formed to have a relatively large height to cover the stacked line patterns, which include the channel semiconductor layers PNS and the sacrificial layers 210. The top surface of the sacrificial gate line 224 may have a flat level. According to embodiments, the sacrificial gate line 224 may be formed of and/or include polysilicon, but is not limited thereto.

Sacrificial gate spacers 228 may be disposed on sidewalls of sacrificial gate line 224 and, according to embodiments, may be formed of and/or include silicon oxide (SiOₓ), silicon nitride (SiNₓ), silicon oxynitride (SiOₓN_{y}), silicon carbonitride (SiCₓN_{y}), silicon oxide carbonitride (SiOₓC_{y}N_{z}), or a combination thereof.

The sacrificial gate capping layer 226 may be disposed on the top surface of the sacrificial gate line 224, and opposing sidewalls of the sacrificial gate capping layer 226 may be covered by the sacrificial gate spacers 228. According to embodiments, the sacrificial gate capping layer 226 may be formed of and/or include a silicon nitride film.

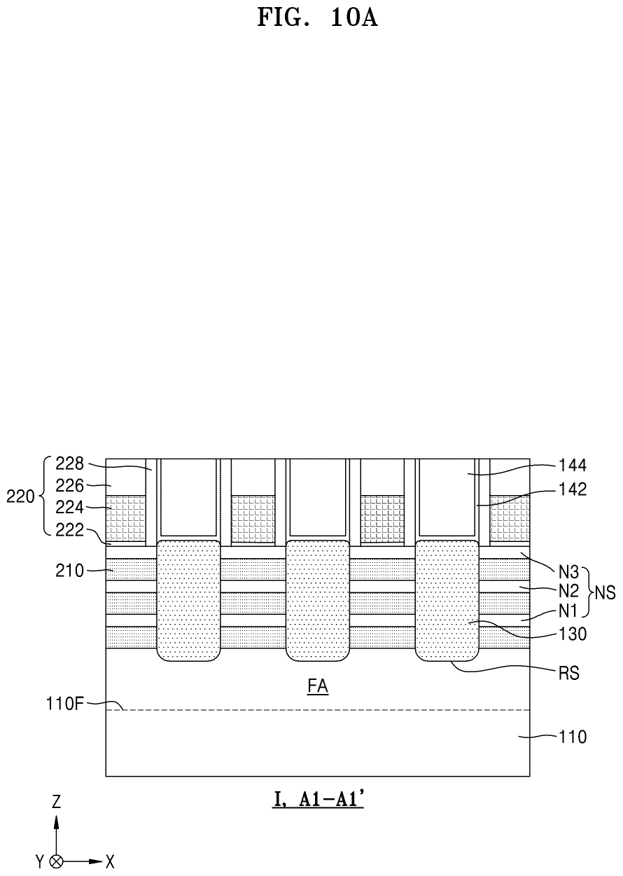

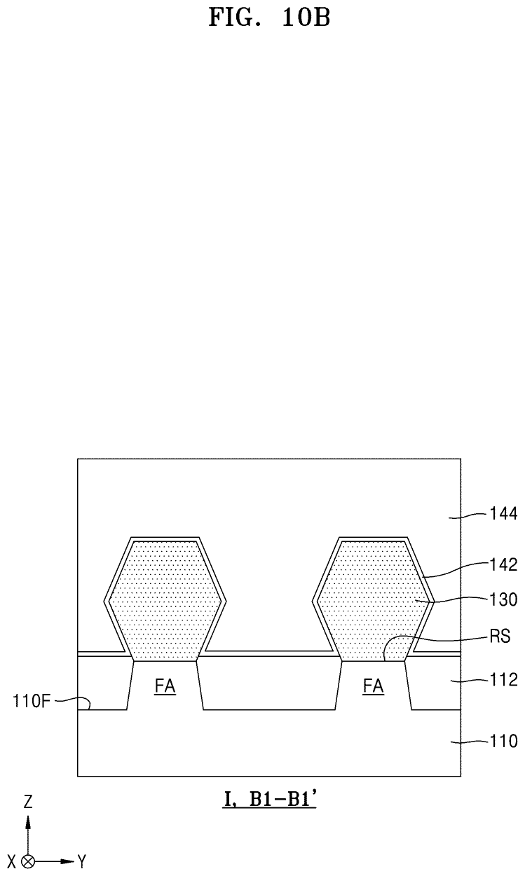

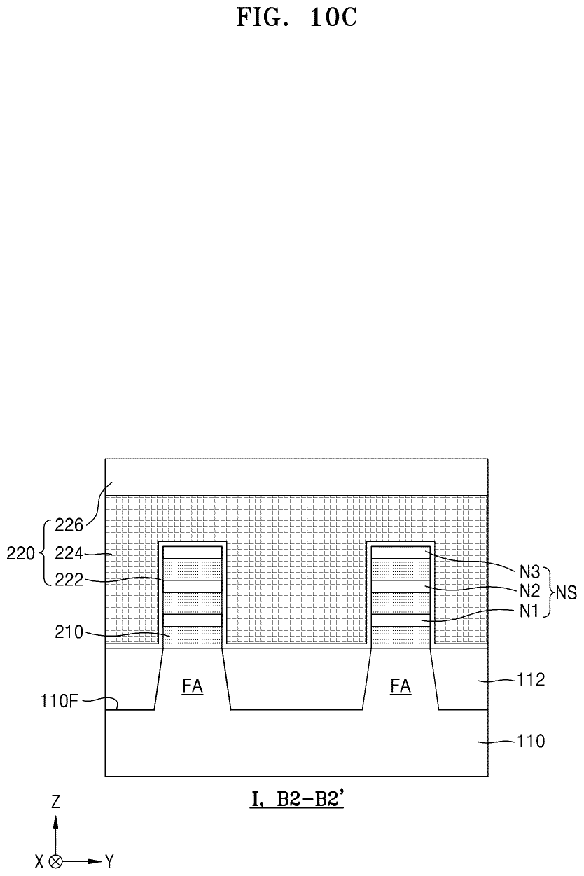

Referring to FIGS. 10A to 10C, recesses RS may be formed on opposing sides of the sacrificial gate structure 220 by etching the stacked line patterns, which include the channel semiconductor layers PNS and the sacrificial layers 210, and a portion of the substrate 110 on opposing sides of the sacrificial gate structure 220. As the recesses RS are formed, the channel semiconductor layers PNS may be separated into the plurality of semiconductor patterns NS. For example, as the recesses RS are formed, a structure in which a plurality of sacrificial layers 210 and a plurality of semiconductor patterns NS are alternately arranged on the fin-type active region FA may be formed.

Thereafter, the source/drain region 130 may be formed in the recesses RS. For example, the source/drain region 130 may be formed by epitaxially growing a semiconductor material from surfaces that are exposed on the inner wall of the recess RS of the plurality of semiconductor patterns NS, the sacrificial layers 210, and the substrate 110.

According to embodiments, the source/drain region 130 may be formed of and/or include a doped SiGe layer, a doped Ge layer, a doped SiC layer, or a doped InGaAs layer, but is not limited thereto. The process for forming the source/drain region 130 may be an epitaxial growth process using a liquid precursor or a gaseous precursor.

According to embodiments, the source/drain region 130 may be formed to have a relatively large thickness to fill the interior of the recess RS. The top surface of the source/drain region 130 may be formed to be disposed at a higher level than the uppermost semiconductor pattern NS.

Thereafter, the passivation layer 142 and the inter-gate insulation layer 144 may be formed to cover sidewalls of the sacrificial gate structure 220 and the source/drain regions 130. The passivation layer 142 may be formed to have a small thickness, and the inter-gate insulation layer 144 may be formed to have a relatively large height to fill the space between two sacrificial gate structures 220 that are adjacent to each other. The top surface of the inter-gate insulation layer 144 may be disposed on the same plane as the top surface of the sacrificial gate structure 220.

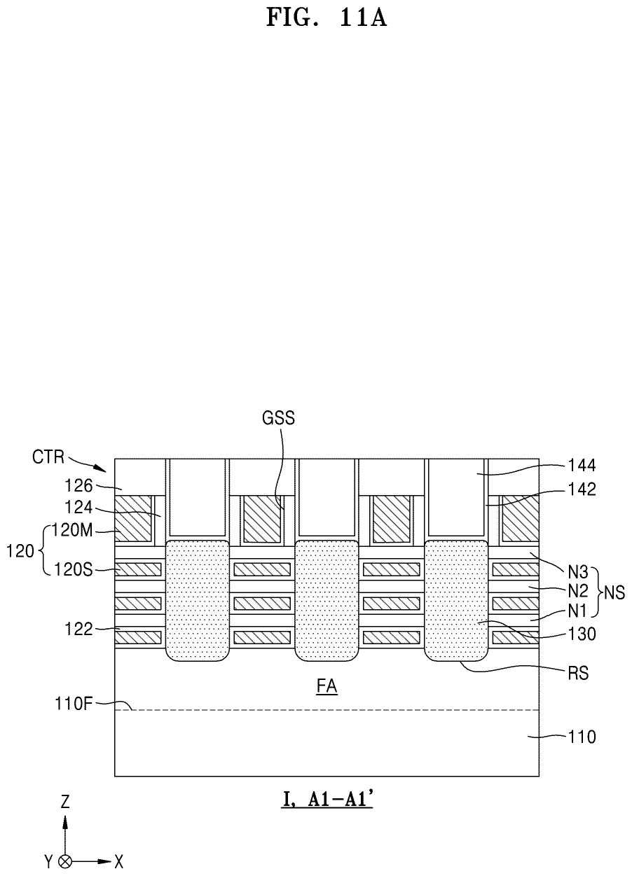

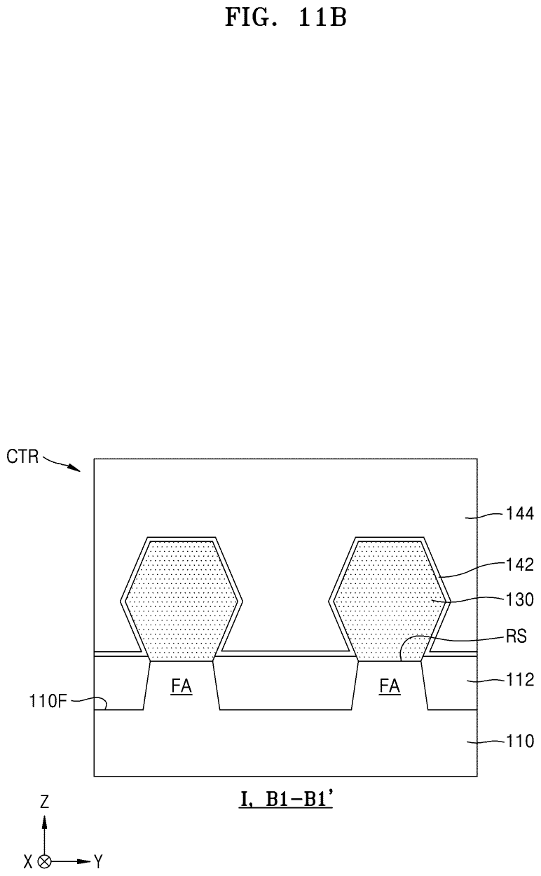

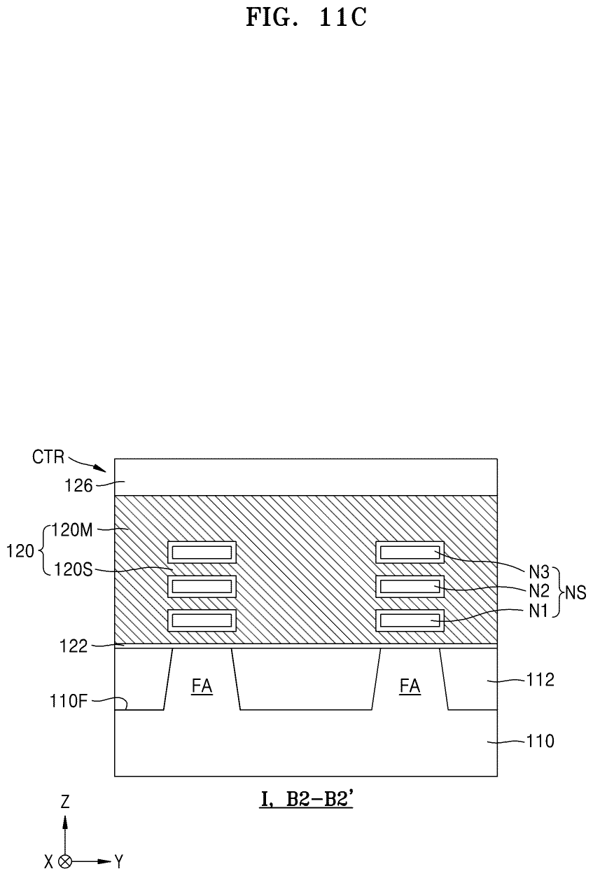

Referring to FIGS. 11A to 11C, the sacrificial gate capping layer 226 may be removed by planarizing upper portions of the sacrificial gate structure 220 and the inter-gate insulation layer 144. The top surface of the sacrificial gate line 224 may be exposed through the planarization process.

Thereafter, the sacrificial gate line 224 and the sacrificial insulation layer pattern 222 may be removed to form a gate space GSS. For example, the gate space GSS may be defined between two sacrificial gate spacers 228 that are adjacent to each other, and sidewalls of the plurality of semiconductor patterns NS and top surfaces and sidewalls of the sacrificial layer 210 may be exposed in the gate space GSS.

Thereafter, the plurality of sacrificial layers 210 remaining on the fin-type active region FA may be removed through the gate space GSS, thereby partially exposing the plurality of semiconductor patterns NS and the top surface of the fin-type active region FA. The process of removing the plurality of sacrificial layers 210 may be a wet etching process using etching selectivity (or a difference in etch rate) between the sacrificial layers 210 and the plurality of semiconductor patterns NS.

Thereafter, the gate insulation layer 122 may be formed on surfaces exposed in the gate space GSS. Thereafter, the gate line 120 filling the gate space GSS may be formed on the gate insulation layer 122. For example, after a work function metal-containing layer (not shown) is conformally formed on the inner wall of the gate space GSS, a gap-fill metal layer (not shown) may be formed on the work function conductive layer to fill the gate space GSS. Thereafter, the gate line 120 may be formed by planarizing the upper portion of the gap-fill metal layer until the top surface of the inter-gate insulation layer 144 is exposed.

According to embodiments, the work function metal-containing layer may be formed of and/or include Al, Cu, Ti, Ta, W, Mo, TaN, NiSi, CoSi, TiN, WN, TiAl, TiAlC, TiAlN, TaCN, TaC, TaSiN, or a combination thereof. The gap-fill metal layer may be formed of and/or include Al, Cu, Ti, Ta, W, Mo, TaN, NiSi, CoSi, TiN, WN, TiAl, TiAlC, TiAlN, TaCN, TaC, TaSiN, or a combination thereof.

Thereafter, upper portions of the gate line 120, the gate insulation layer 122, and the sacrificial gate spacer 228 may be removed, and the gate capping layer 126 may be formed in an upper portion of the gate space GSS. Here, remaining portions of the sacrificial gate spacers 228 may be referred to as the outer insulation spacers 124.

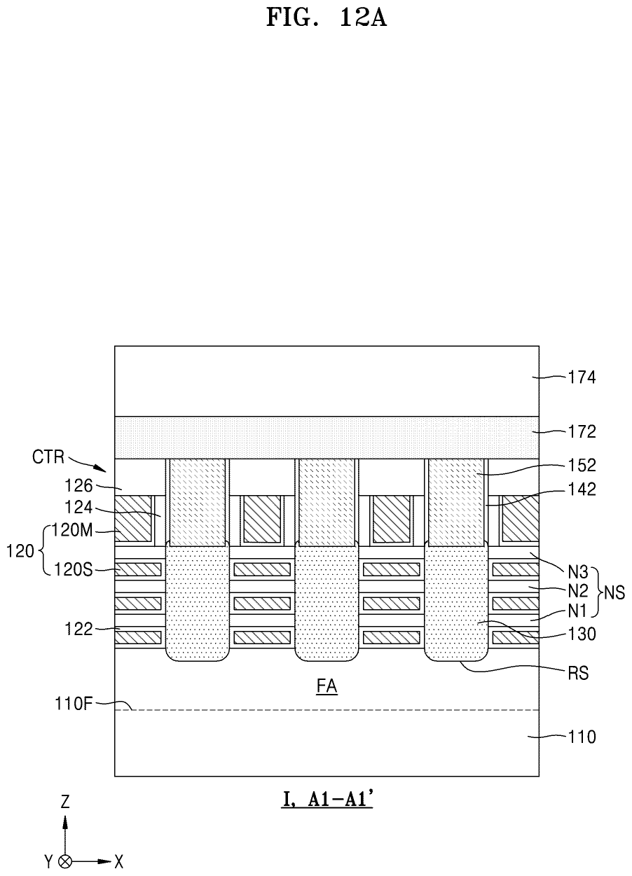

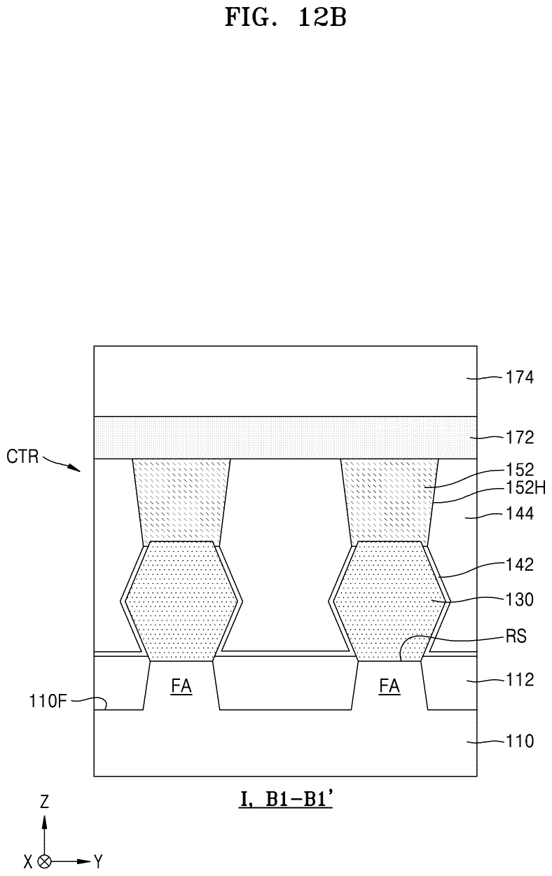

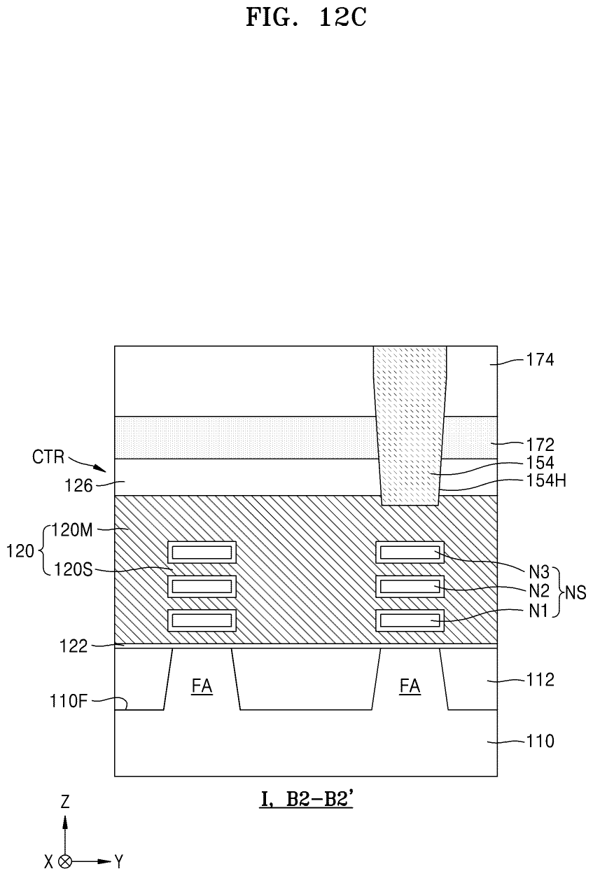

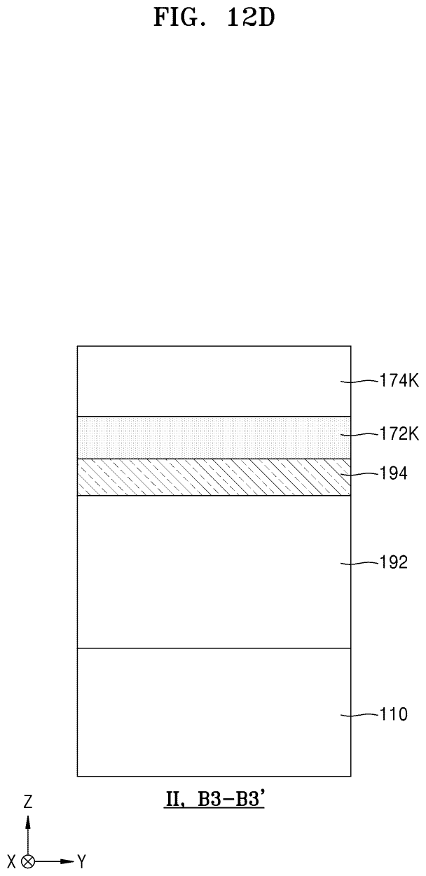

Referring to FIGS. 12A to 12D, a mask pattern may be formed on the gate capping layer 126 and the inter-gate insulation layer 144, and a portion of the inter-gate insulation layer 144 may be removed to form the first contact hole 152H exposing the top surface of the source/drain region 130. Thereafter, the first contact 152 may be formed in the first contact hole 152H.

According to embodiments, the first contact 152 may be formed of and/or include at least one of Mo, MON, Co, CON, W, WN, Ru, RuN, Ti, or TiN.

According to some embodiments, before forming the first contact 152, a metal silicide film which may include tungsten silicide, cobalt silicide, nickel silicide, etc. may be formed at the bottom of the first contact hole 152H, and the first contact 152 may be formed on the metal silicide film.

Thereafter, the lower insulation layer 172 covering the first contact 152 may be formed on the gate capping layer 126 and the inter-gate insulation layer 144, and the first interlayer insulation layer 174 may be formed on the lower insulation layer 172.

According to embodiments, the lower insulation layer 172 may be formed of and/or include silicon nitride, and the first interlayer insulation layer 174 may be formed of and/or include silicon oxide or a low-k dielectric material.

Thereafter, a mask pattern may be formed on the first interlayer insulation layer 174, and portions of the first interlayer insulation layer 174, the lower insulation layer 172, and the gate capping layer 126 may be removed to form the second contact hole 154H exposing the top surface of the gate line 120.

Thereafter, the second contact hole 154H may be filled with a conductive material, and the upper portion of the conductive material may be planarized until the top surface of the first interlayer insulation layer 174 is exposed to form the second contact 154. The second contact 154 may have the top surface disposed at the same level as the top surface of the first interlayer insulation layer 174.

According to embodiments, the second contact 154 may be formed of and/or include at least one of Mo, MON, Co, CON, W, WN, Ru, RuN, Ti, or TiN.

Meanwhile, as shown in FIG. 12D, on the scribe lane region II of the substrate 110, the lower buried layer 192, the first insulation layer 194, the second insulation layer 172K, and the third insulation layer 174K may be sequentially arranged.

According to embodiments, the channel semiconductor layers PNS and the sacrificial layers 210 formed on the scribe lane region II of the substrate 110 may be removed, and the space formed by removing the channel semiconductor layers PNS and the sacrificial layers 210 may be filled with the lower buried layer 192. The lower buried layer 192 may be formed of and/or include silicon oxide.

The first insulation layer 194 may be formed on the lower buried layer 192 and may be formed of and/or include silicon nitride. The first insulation layer 194 may be formed simultaneously in the process for forming the gate capping layer 126, but the inventive concept is not limited thereto. The second insulation layer 172K may be formed on the first insulation layer 194 and may be formed of and/or include silicon nitride. The second insulation layer 172K may be formed simultaneously in the process for forming the lower insulation layer 172, but the inventive concept is not limited thereto. The third insulation layer 174K may be formed on the second insulation layer 172K and may be formed of and/or include silicon oxide or a low-k dielectric material. The third insulation layer 174K may be formed simultaneously in the process for forming the second insulation layer 172K, but the inventive concept is not limited thereto.

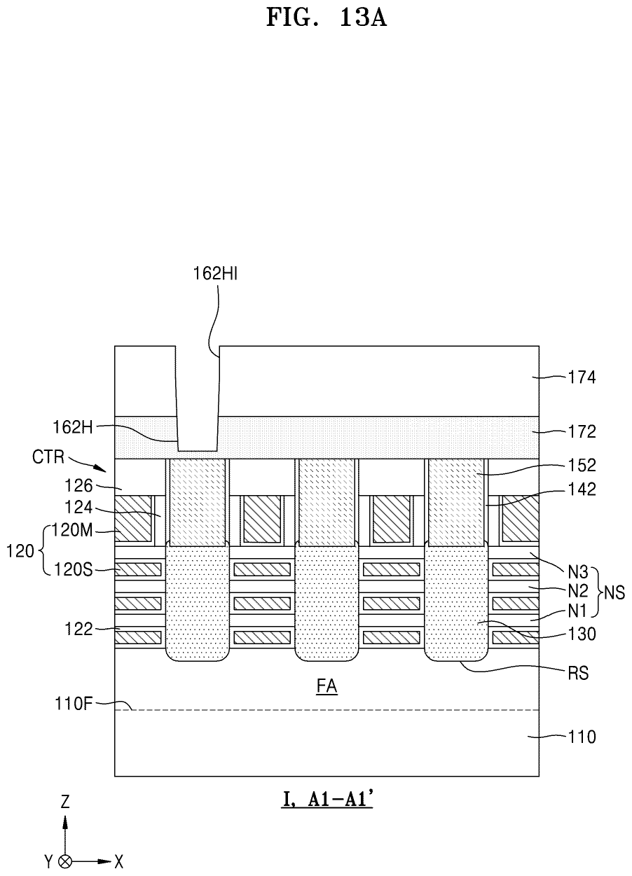

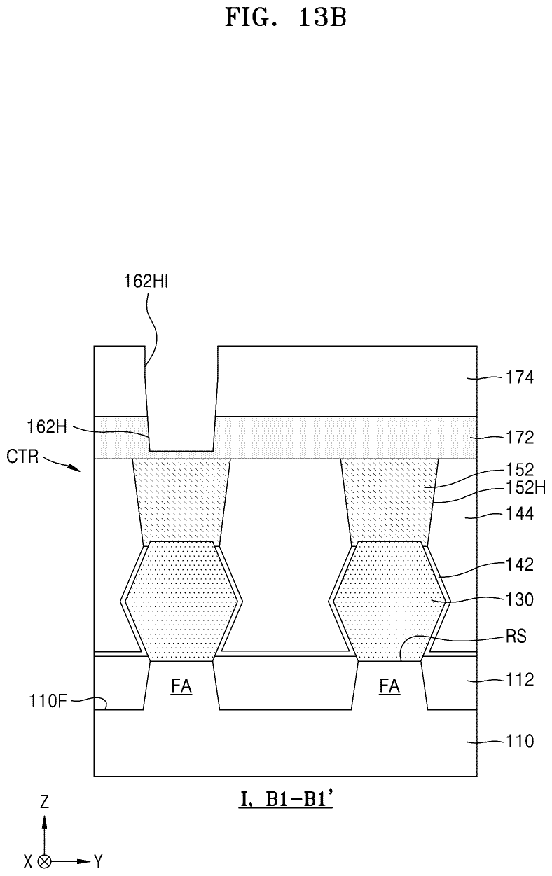

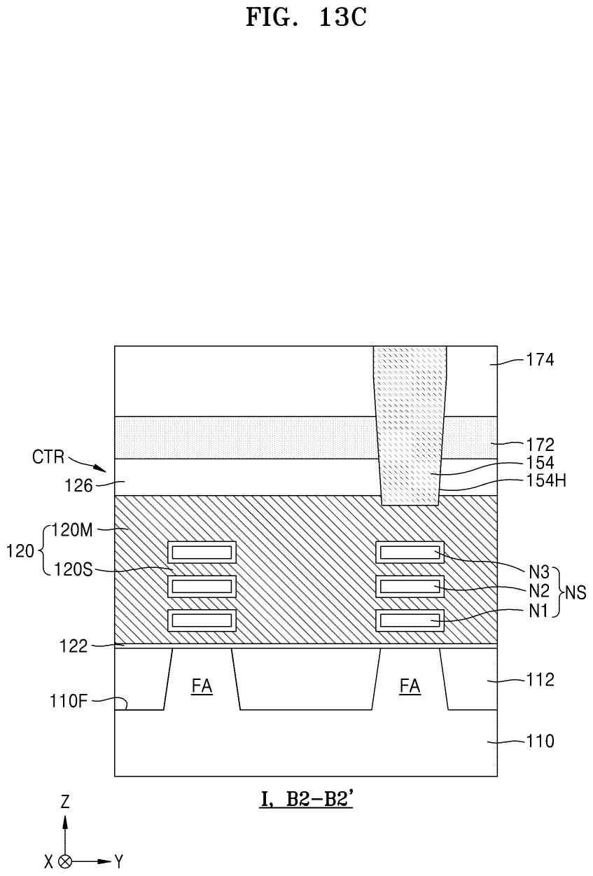

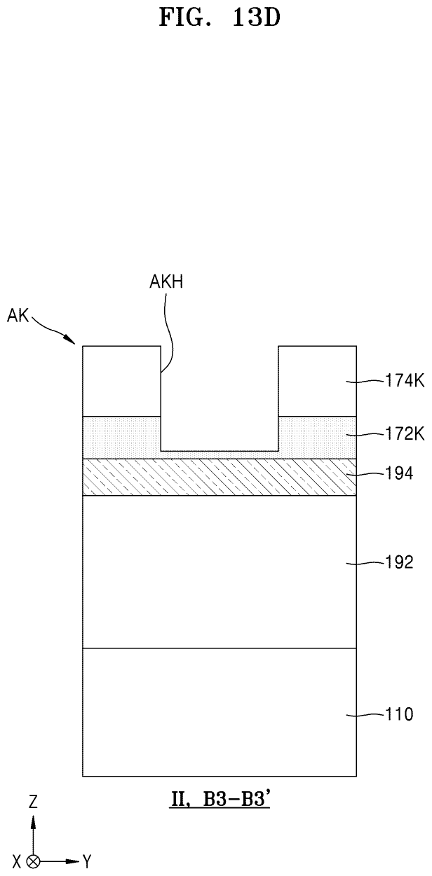

Referring to FIGS. 13A to 13D, the first via hole 162H may be formed by removing portions of the first interlayer insulation layer 174 and the lower insulation layer 172. The first via hole 162H may be formed to a depth to completely penetrate through the first interlayer insulation layer 174 but not to completely penetrate through the lower insulation layer 172 such that the first contact 152 is not exposed at the bottom of the first via hole 162H.

Meanwhile, the alignment hole AKH may be formed by removing portions of the third insulation layer 174K and the second insulation layer 172K on the scribe lane region II of the substrate 110. The alignment hole AKH may have a rectangular shape with a relatively large width or a bar-like shape in a plan view.

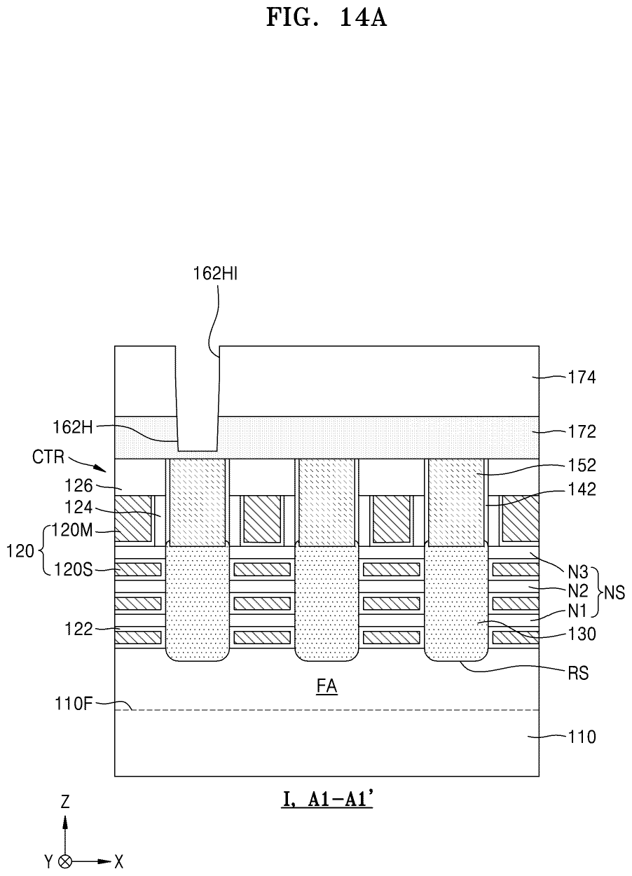

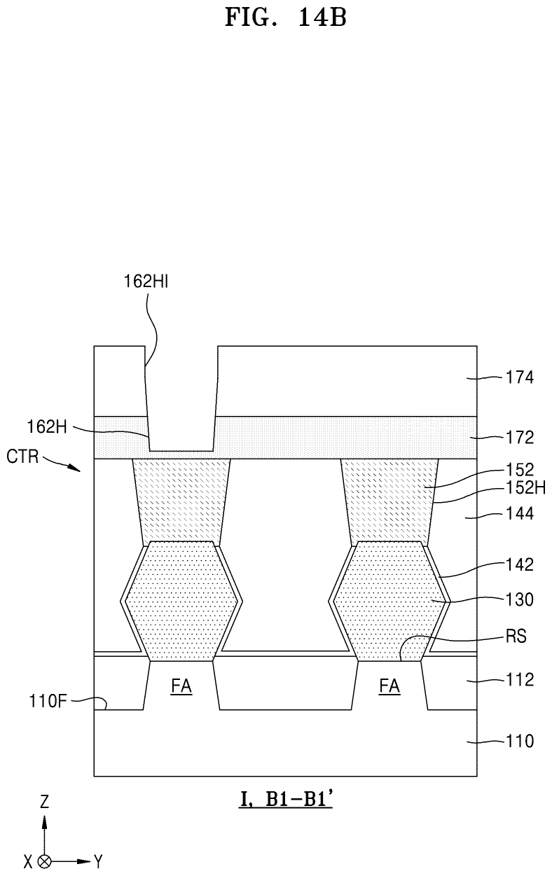

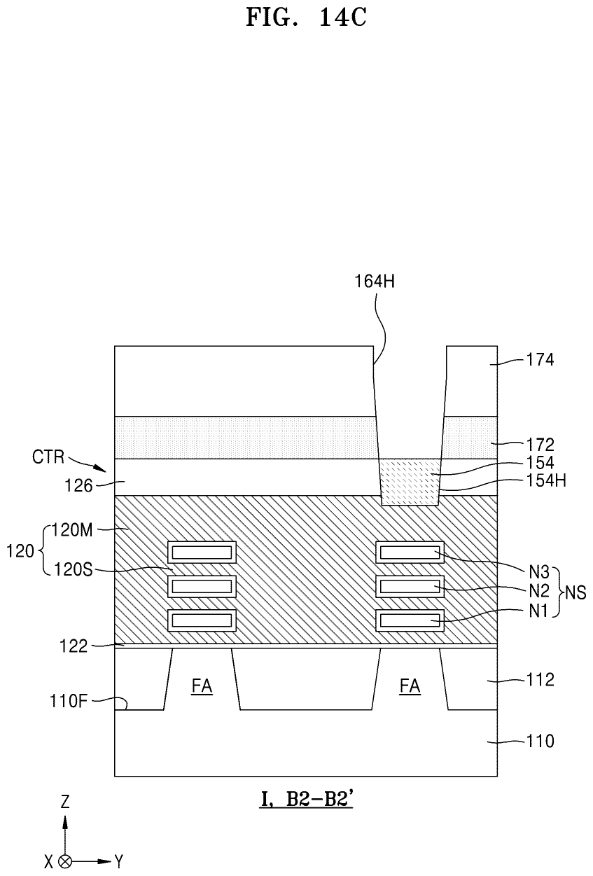

Referring to FIGS. 14A to 14C, the upper portion of the second contact 154 disposed inside the second contact hole 154H may be removed through a recess process.

According to embodiments, the recess process may include an etching process using a chlorine-based plasma, a wet etching process using a chlorine-based etchant, or a dry etching process. According to some embodiments in which the second contact 154 is formed of and/or includes molybdenum, the chlorine-based etchant may be MoCl₅ or MoO₂Cl₂.

The top surface of the second contact 154 may be lowered through a process of removing the upper portion of the second contact 154, and thus the second contact 154 may have the top surface disposed at the same level as that of the gate capping layer 126. Also, the second contact 154 may have the top surface disposed at the same level as that of the first contact 152.

Through the recess process to remove the upper portion of the second contact 154, the upper portion of the second contact hole 154H disposed at a vertical level higher than that of the lowered top surface of the second contact 154 may be exposed again. The upper portion of the second contact hole 154H may be referred to as the second via hole 164H.

Meanwhile, according to other embodiments, the second contact hole 154H may be formed to penetrate through the lower insulation layer 172 and the gate capping layer 126, and, after the second contact 154 is formed within the second contact hole 154H, the first interlayer insulation layer 174 may be formed to cover the top surface of the second contact 154. In this case, an etching process to form the second via hole 164H may be performed separately, and, for example, the second via hole 164H may be formed by removing a portion of the first interlayer insulation layer 174. The top surface of the second contact 154 may be disposed at the bottom of the second via hole 164H.

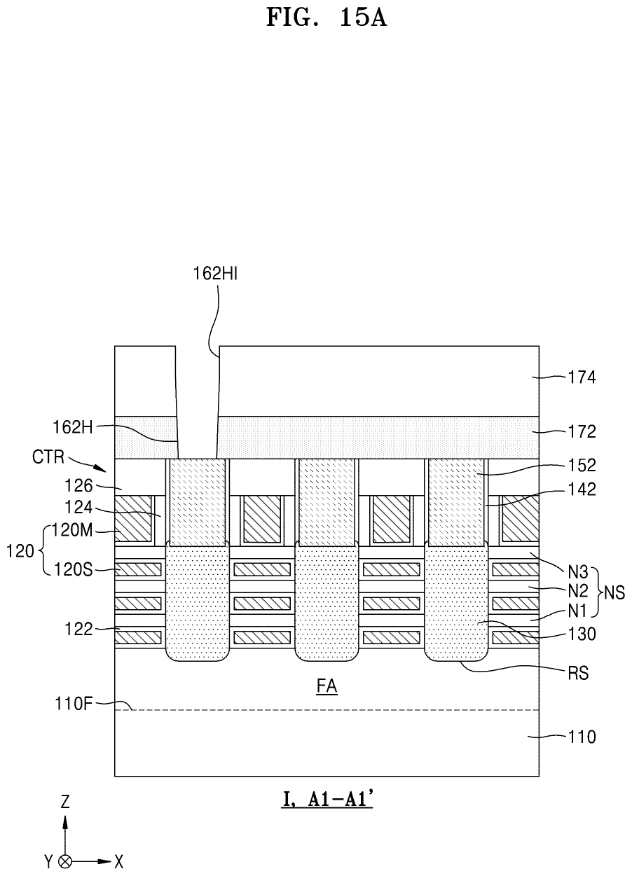

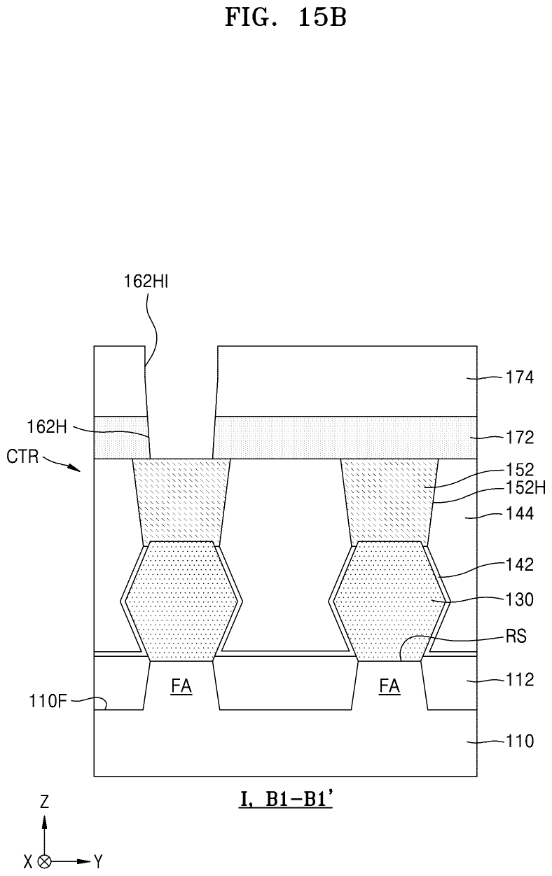

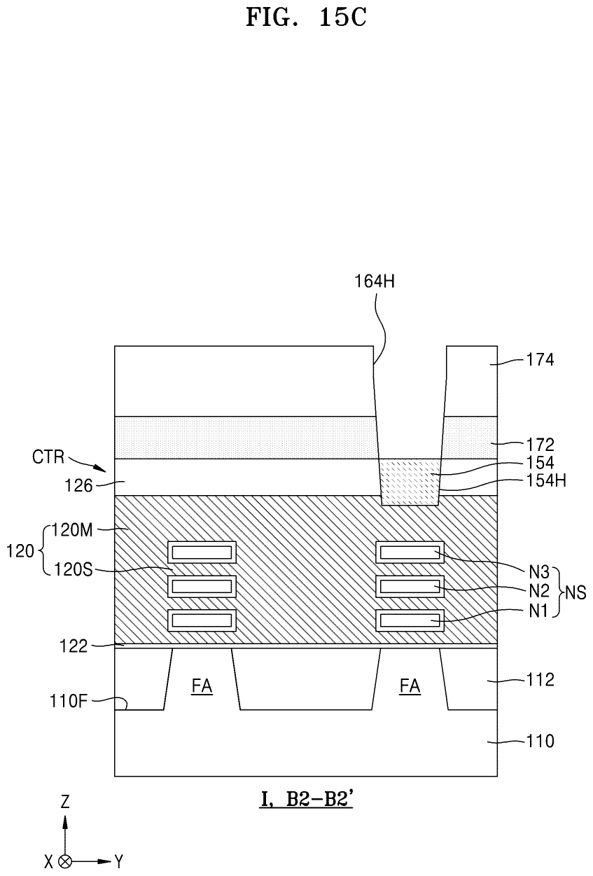

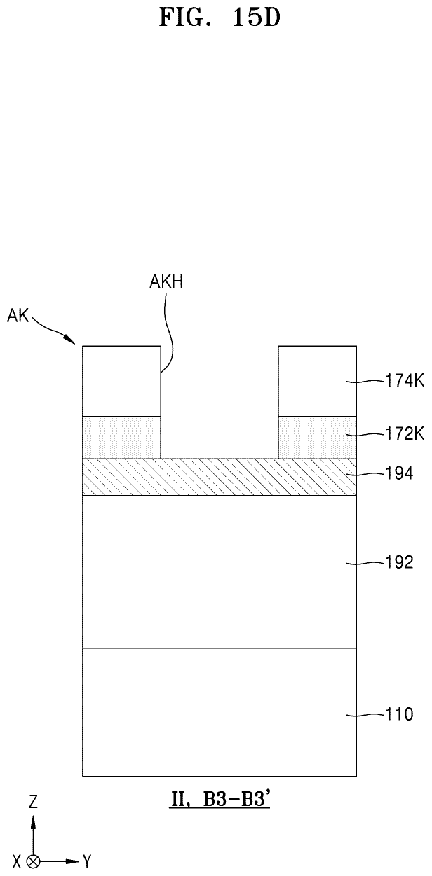

Referring to FIGS. 15A to 15C, an etching process may be performed to further extend or lower the bottom of the first via hole 162H downward to expose the top surface of the first contact 152. For example, during the etching process, the top surface of the first contact 152 may be exposed at the bottom of the first via hole 162H.

According to embodiments, during the etching process, the bottom portion of the alignment hole AKH may be further extended downward, and thus the top surface of the first insulation layer 194 may be exposed at the bottom of the alignment hole AKH.

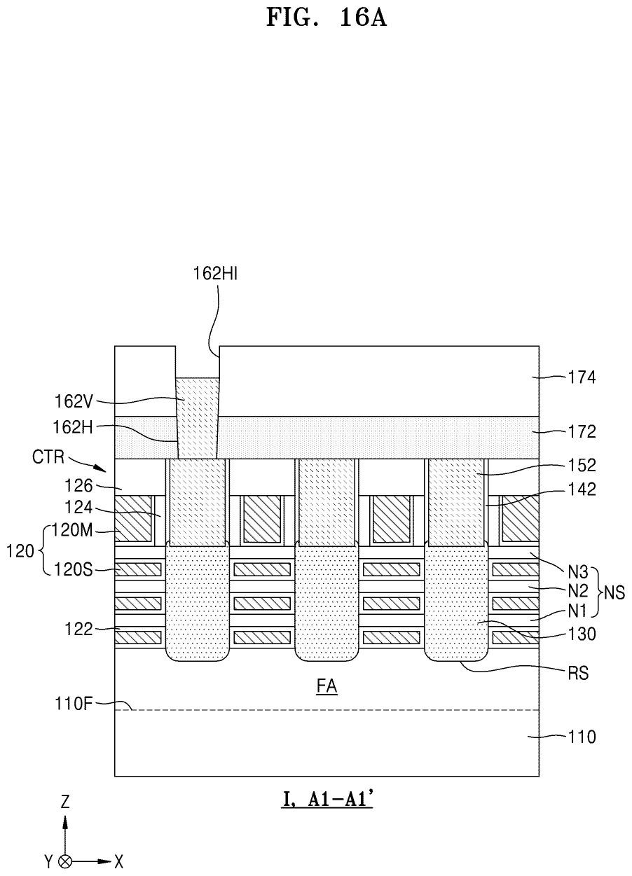

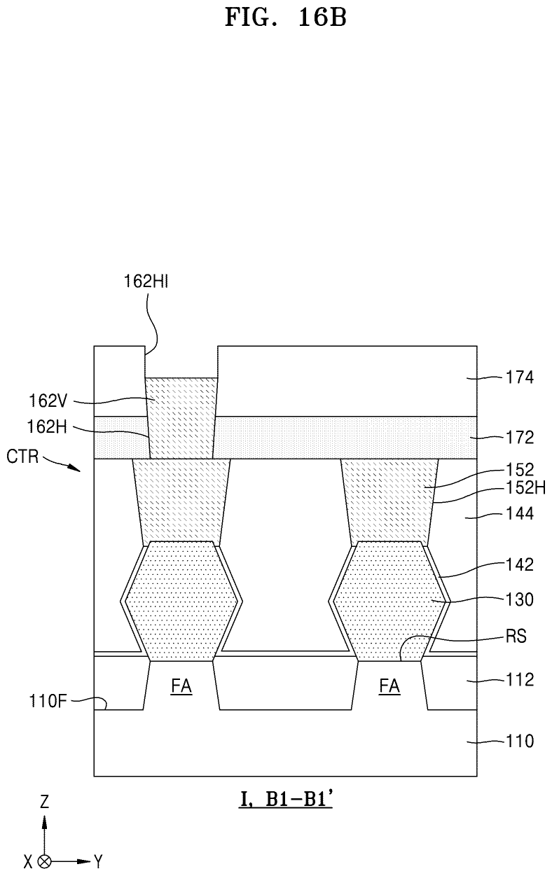

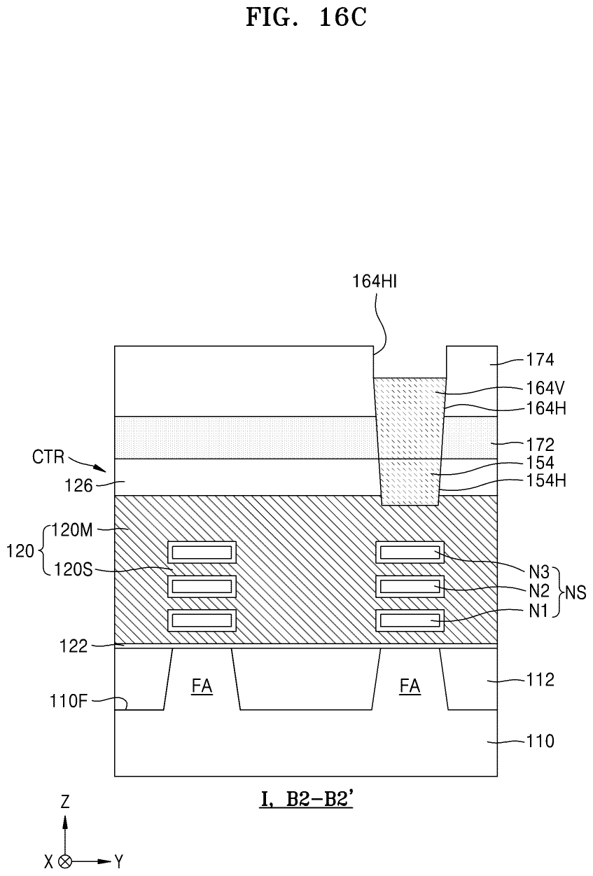

Referring to FIGS. 16A to 16C, the first via conductive layer 162V may be formed in the first via hole 162H, and the second via conductive layer 164V may be formed in the second via hole 164H.

According to embodiments, the process of forming the first via conductive layer 162V may be performed simultaneously with the process of forming the second via conductive layer 164V. According to other embodiments, the first via conductive layer 162V may first be formed in the first via hole 162H, and then the second via conductive layer 164V may be formed in the second via hole 164H. According to other embodiments, the second via conductive layer 164V may first be formed in the second via hole 164H, and then the first via conductive layer 162V may be formed in the first via hole 162H.

According to embodiments, the first via conductive layer 162V and the second via conductive layer 164V may each be formed of and/or include at least one of molybdenum, ruthenium, or tungsten.

According to embodiments, the first via conductive layer 162V and the second via conductive layer 164V may be formed by bottom-up filling the first via hole 162H and the second via hole 164H. According to embodiments, the process of forming the first via conductive layer 162V and the second via conductive layer 164V may be performed through a chemical vapor deposition process, an atomic layer deposition process, or a physical vapor deposition process. For example, when the first via conductive layer 162V and the second via conductive layer 164V are formed of and/or include molybdenum, a reactant containing a molybdenum precursor of MoCl₅ or MoO₂Cl₂ and H2 may be supplied to a chamber and the first via conductive layer 162V and the second via conductive layer 164V may be formed in a bottom-up filling manner.

According to embodiments, the first via conductive layer 162V and the second via conductive layer 164V may not completely fill the inside of the first via hole 162H and the second via hole 164H, respectively. For example, the inlet portion 162HI of the first via hole 162H and an inlet portion 164HI of the second via hole 164H may not be filled.

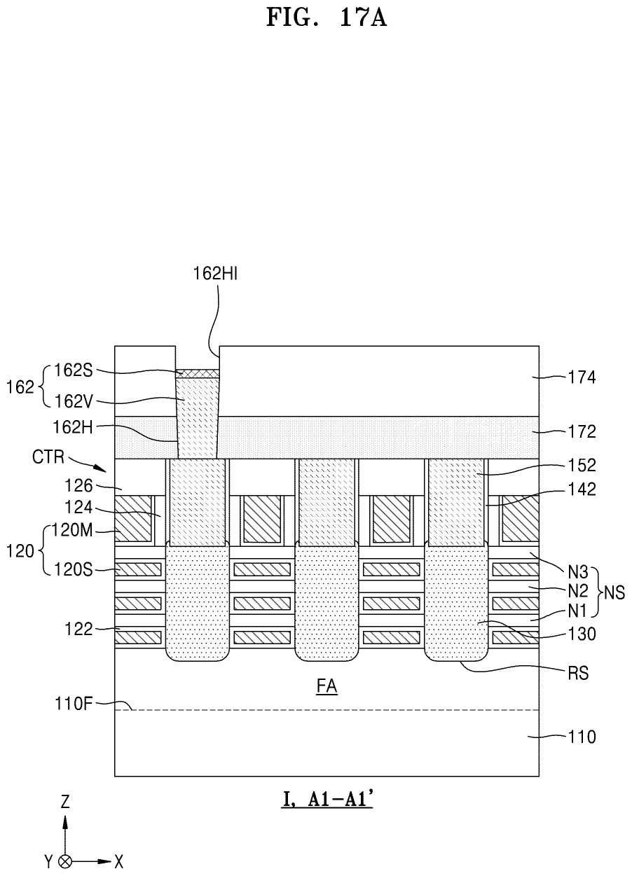

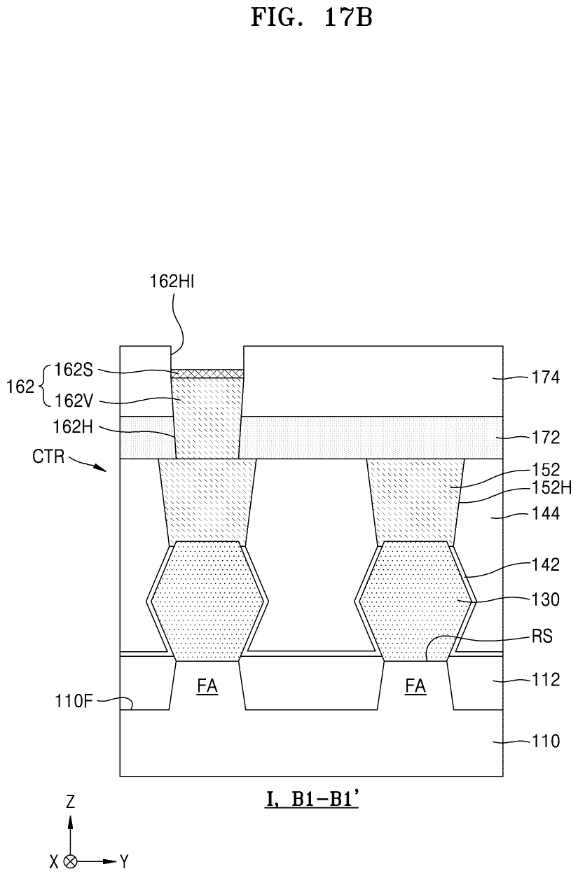

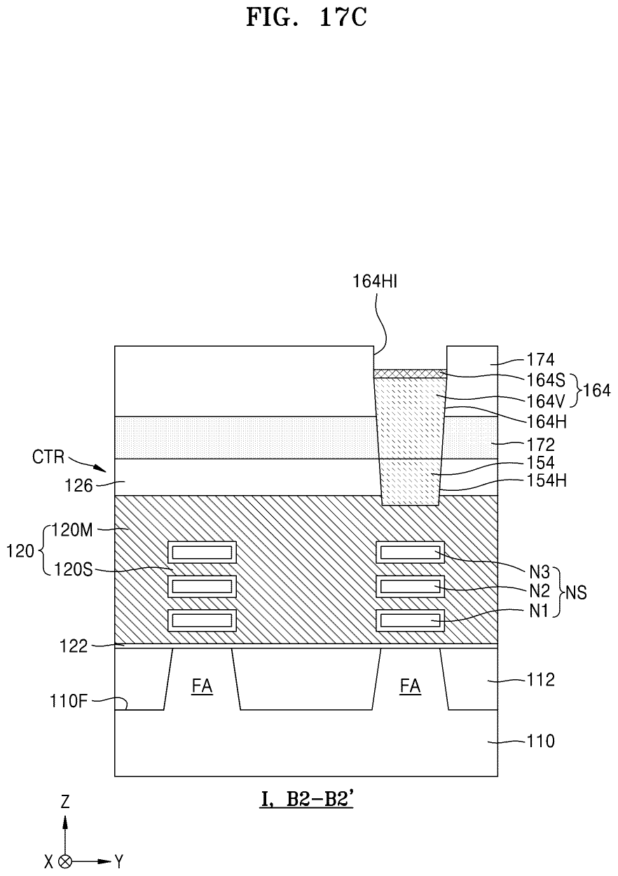

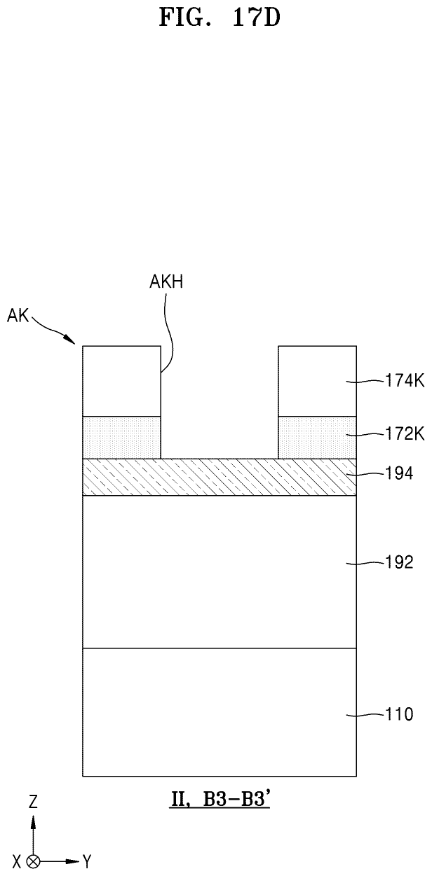

Referring to FIGS. 17A to 17D, the first via skin layer 162S may be formed on the top surface of the first via conductive layer 162V, and the second via skin layer 164S may be formed on the top surface of the second via conductive layer 164V.

According to embodiments, the process of forming the first via skin layer 162S may be performed simultaneously with the process of forming the second via skin layer 164S. According to other embodiments, the first via skin layer 162S may first be formed in the first via hole 162H, and then the second via skin layer 164S may be formed in the second via hole 164H. According to other embodiments, the second via skin layer 164S may first be formed in the second via hole 164H, and then the first via skin layer 162S may be formed in the first via hole 162H.

According to embodiments, the first via skin layer 162S and the second via skin layer 164S may be formed of and/or include tungsten or ruthenium.

According to embodiments, the first via skin layer 162S and the second via skin layer 164S may be formed on the top surfaces of the first via conductive layer 162V and the second via conductive layer 164V through selective metal deposition processes, respectively. According to embodiments, when the first via skin layer 162S and the second via skin layer 164S are formed of and/or include tungsten, a precursor including WF₆ and a reactant including H2 are supplied into a chamber during the selective metal deposition processes, and thus the first via skin layer 162S and the second via skin layer 164S may be formed on the top surfaces of the first via conductive layer 162V and the second via conductive layer 164V, respectively.

According to embodiments, the first via skin layer 162S may be formed only on the entire top surface of the first via conductive layer 162V within the first via hole 162H and may not be formed on the top surface and sidewalls of the first interlayer insulation layer 174. Also, the second via skin layer 164S may be formed only on the entire top surface of the second via conductive layer 164V within the second via hole 164H and may not be formed on the top surface and sidewalls of the first interlayer insulation layer 174.

Also, as shown in FIG. 17D, a metal material layer may not be formed at the bottom or on the sidewall of the alignment hole AKH in the scribe lane region II. For example, as the first via conductive layer 162V and the second via conductive layer 164V are formed in a bottom-up filling manner and the first via skin layer 162S and the second via skin layer 164S are formed through selective metal deposition processes, a metal material such as molybdenum or tungsten may not be formed on the inner wall of the alignment hole AKH including an insulation material.

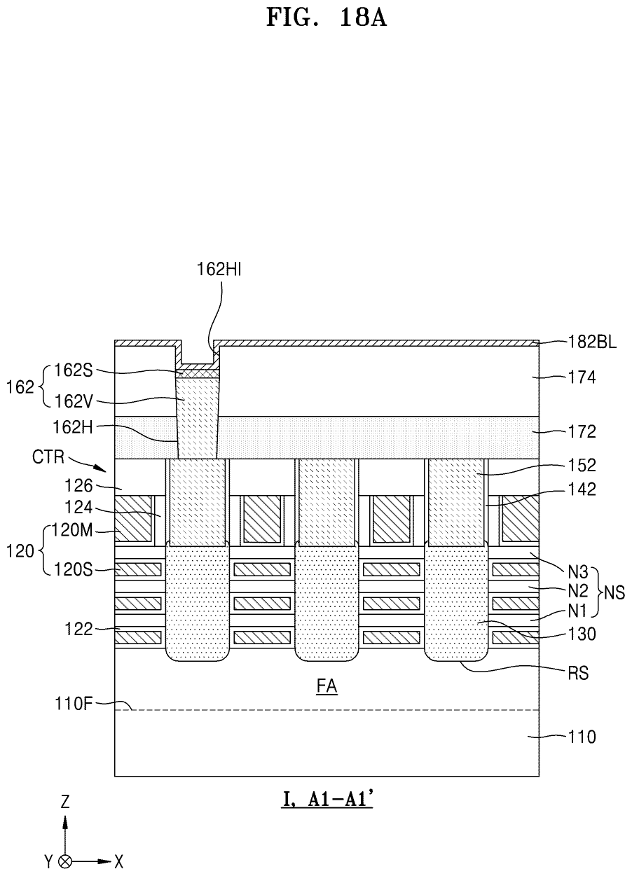

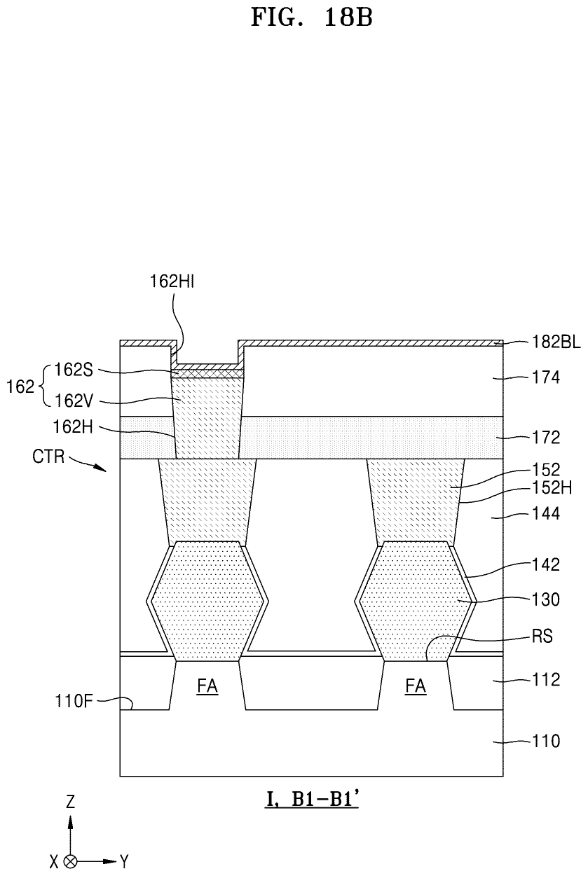

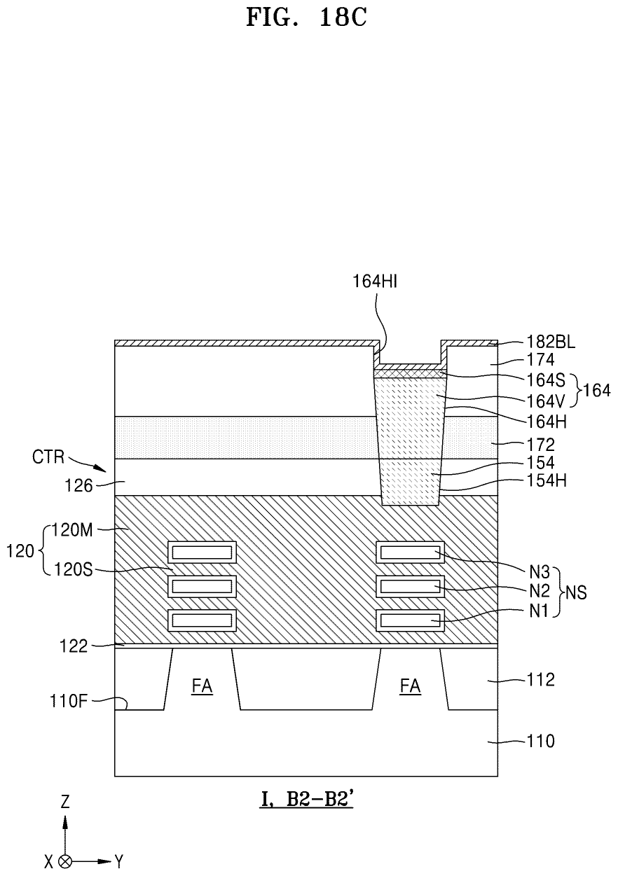

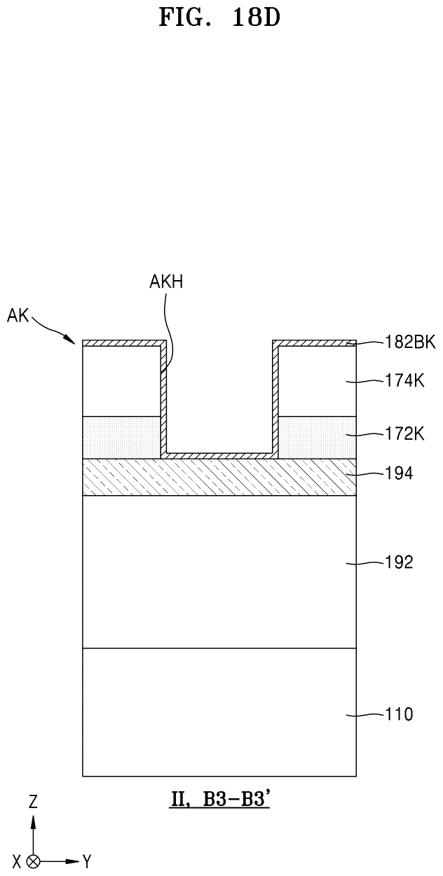

Referring to FIGS. 18A to 18D, a bottom barrier layer 182BL may be formed on the first interlayer insulation layer 174.

According to embodiments, the bottom barrier layer 182BL may be formed of and/or include molybdenum. The bottom barrier layer 182BL may be formed to have a thickness within the range of from about 0.5 nm to about 5 nm and may be conformally disposed on the inner wall of the first via hole 162H and the inner wall of the second via hole 164H. Portions of the bottom barrier layer 182BL arranged on the inner wall of the first via hole 162H and the inner wall of the second via hole 164H may cover the top surface of the first via skin layer 162S and the top surface of the second via skin layer 164S.

According to embodiments, in the process of forming the bottom barrier layer 182BL, an alignment pattern barrier layer 182BK may be formed on the inner wall of the alignment hole AKH and on the top surface of the third insulation layer 174K, in the scribe lane region II. The alignment pattern barrier layer 182BK may be formed of and/or include molybdenum.

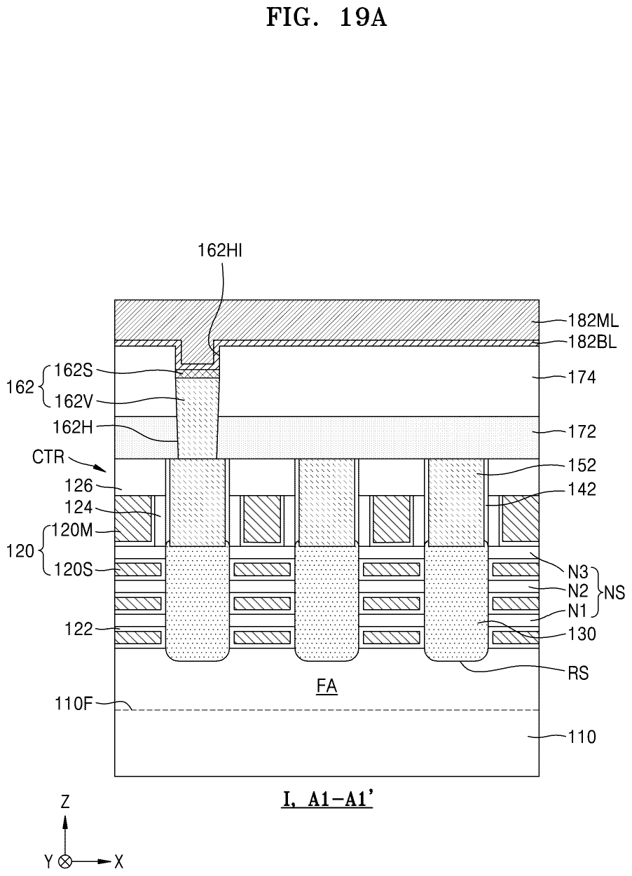

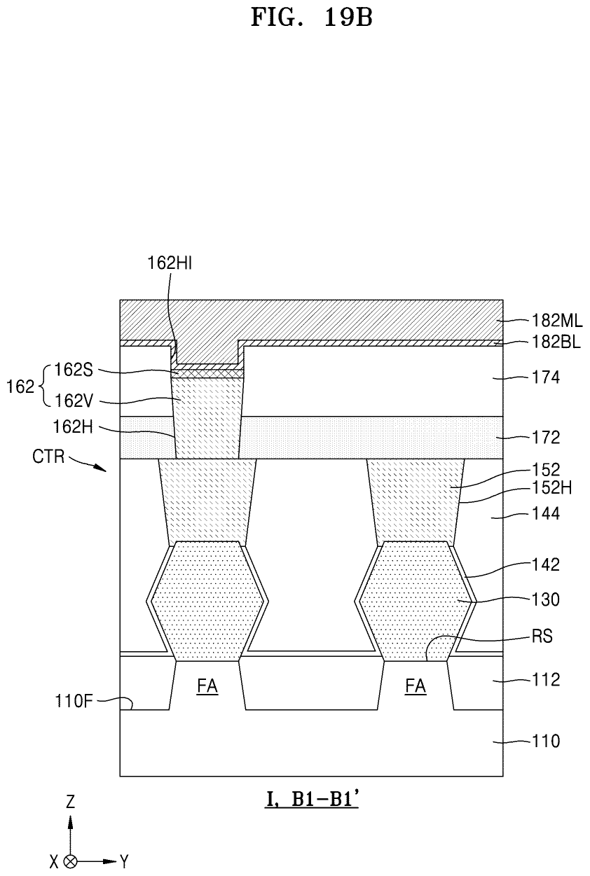

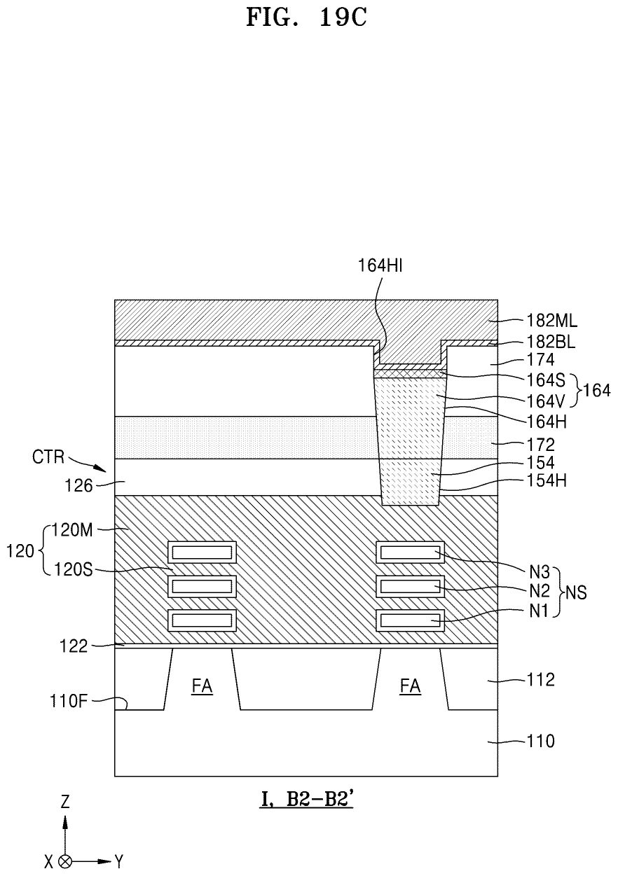

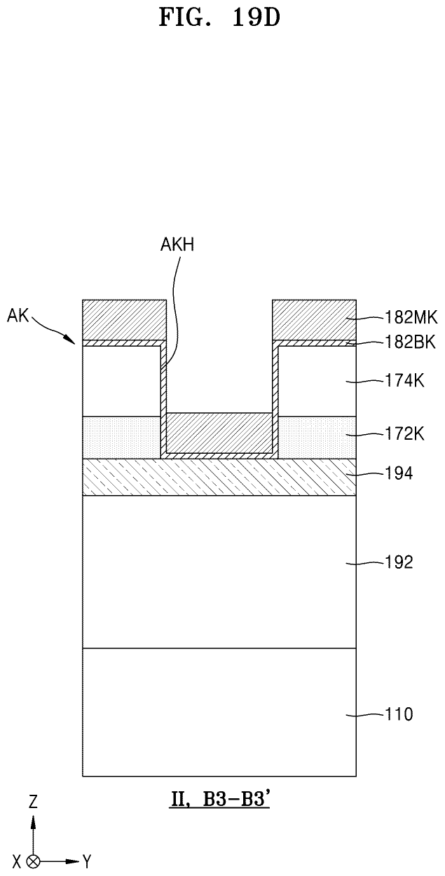

Referring to FIGS. 19A to 19D, a main conductive layer 182ML may be formed on the bottom barrier layer 182BL.

According to embodiments, the main conductive layer 182ML may be formed of and/or include at least one of tungsten, ruthenium, or molybdenum. The main conductive layer 182ML may be formed to a sufficient thickness to cover the entire top surface of the bottom barrier layer 182BL and completely fill the interior of the first via hole 162H and the interior of the second via hole 164H.

According to embodiments, in the process of forming the main conductive layer 182ML, an alignment pattern conductive layer 182MK may be formed on the inner wall of the alignment hole AKH and on the top surface of the third insulation layer 174K, in the scribe lane region II. The alignment pattern conductive layer 182MK may be formed of and/or include at least one of tungsten, ruthenium, or molybdenum.

According to embodiments, the thickness of a portion of the alignment pattern conductive layer 182MK formed at the bottom of the alignment hole AKH may be substantially equal to the thickness of a portion of the alignment pattern conductive layer 182MK formed on the top surface of the third insulation layer 174K. In other words, the difference between the level of the top surface of the alignment pattern conductive layer 182MK inside the alignment hole AKH and the level of the top surface of the alignment pattern conductive layer 182MK outside the alignment hole AKH may be substantially equal to the difference between the level of the top surface of the first insulation layer 194 inside the alignment hole AKH and the level of the top surface of the third insulation layer 174K outside the alignment hole AKH. Therefore, the difficulty of an alignment process using the alignment hole AKH as a mark pattern may be reduced.

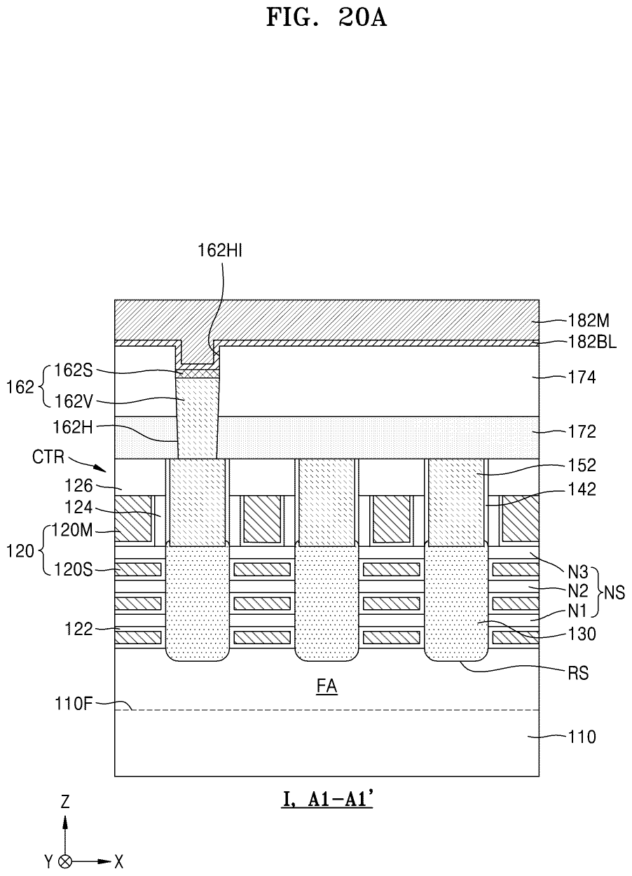

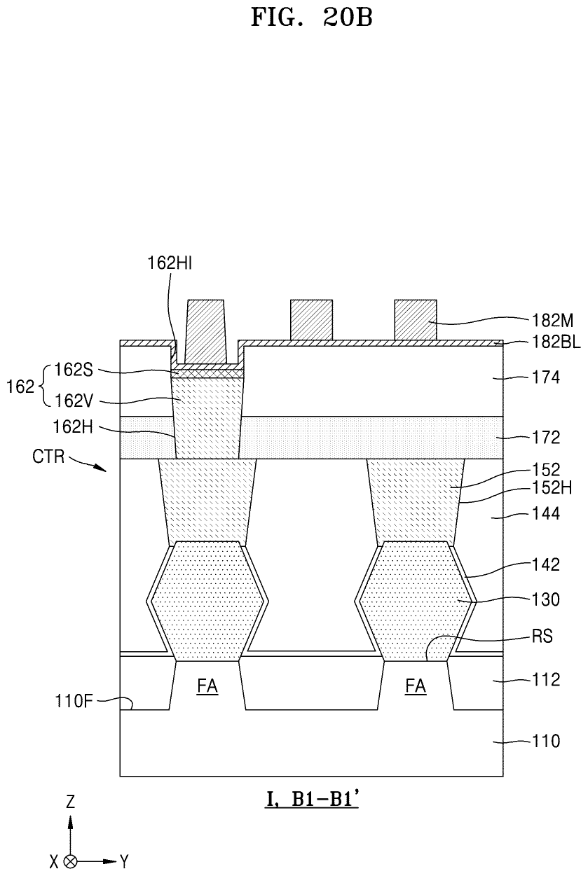

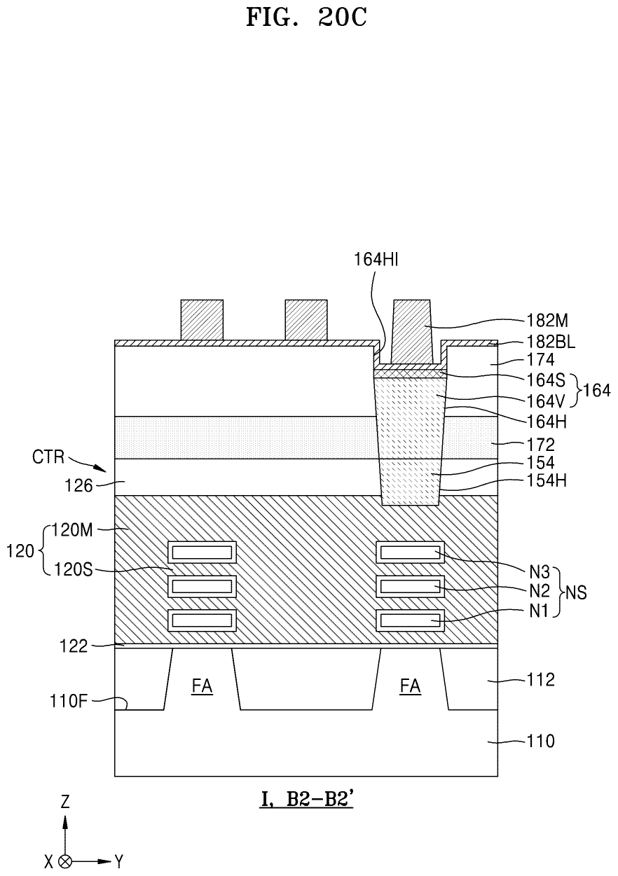

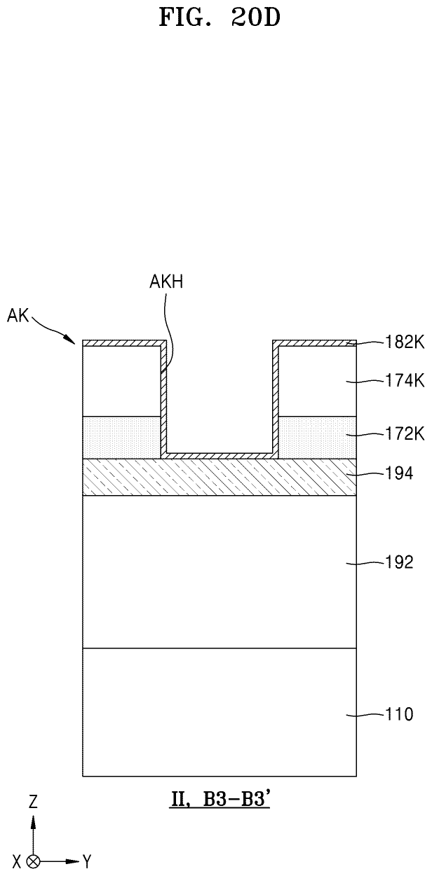

Referring to FIGS. 20A to 20D, a mask pattern may be formed on the top surface of the main conductive layer 182ML, and the main conductive line 182M may be formed by patterning the main conductive layer 182ML by using the mask pattern as an etching mask.

According to embodiments, the main conductive line 182M may include a plurality of line patterns extending in the first horizontal direction X. According to embodiments, the patterning process for forming the main conductive line 182M may be an etching process using a fluorine-based etchant. Alternatively, the patterning process for forming the main conductive line 182M may be an etching process using fluorine plasma.

During the patterning process, the upper portion of the main conductive line 182M may be exposed to the etching atmosphere for a longer period of time. Therefore, the width of the upper portion of the main conductive line 182M may be smaller than the width of the lower portion of the main conductive line 182M, and the distance between both sidewalls of the upper portion of the main conductive line 182M may be smaller than the distance between both sidewalls of the lower portion of the main conductive line 182M. For example, a sidewall of the main conductive line 182M may be inclined at the inclination angle a2 from about 90 degrees to about 110 degrees with respect to the top surface of the substrate 110.

During the patterning process, the top surface of the first interlayer insulation layer 174 may be covered by the bottom barrier layer 182BL and may not be exposed to the etching atmosphere. Therefore, etching damage that would normally occur when silicon oxide or a low-k dielectric material is exposed to the etching atmosphere during an etching process using a fluorine-based etchant or fluorine plasma may be prevented.

According to embodiments, in the process of patterning the main conductive line 182M, the alignment pattern conductive layer 182MK disposed on the inner wall of the alignment hole AKH and on the top surface of the third insulation layer 174K in the scribe lane region II may be removed.

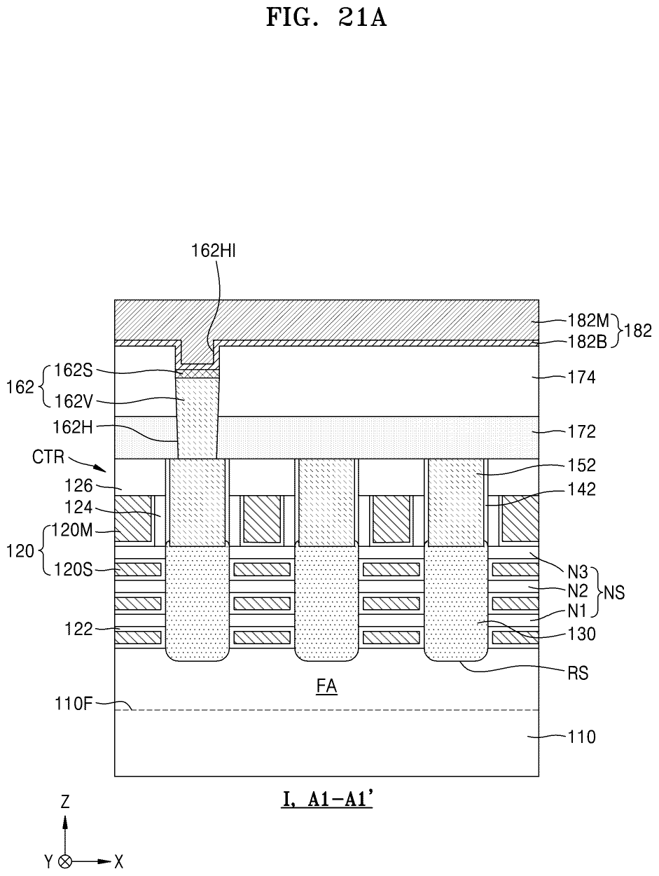

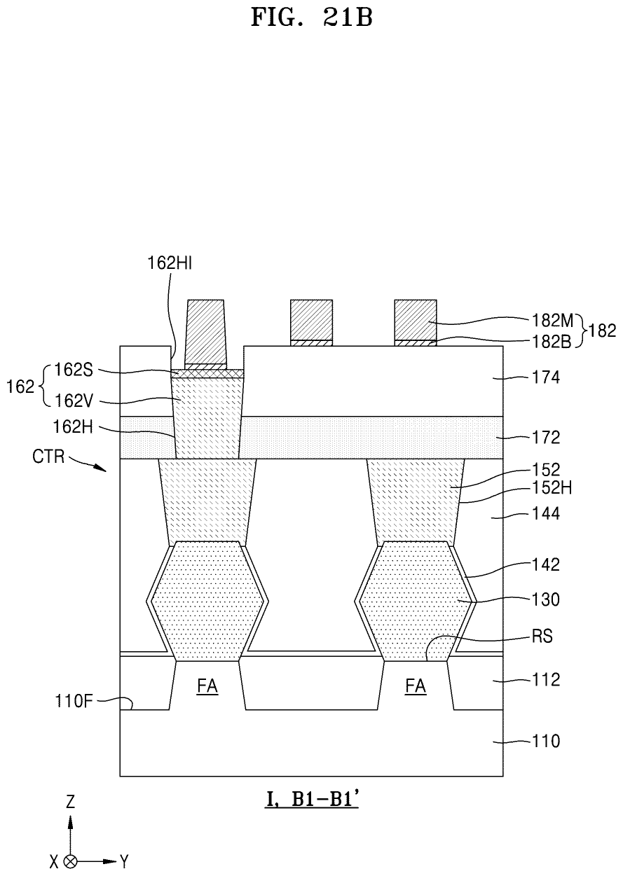

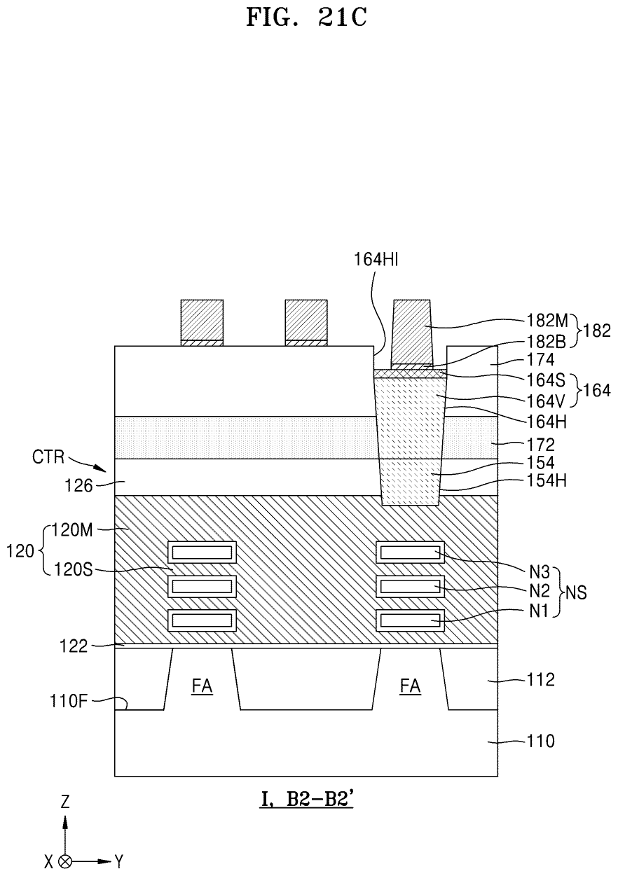

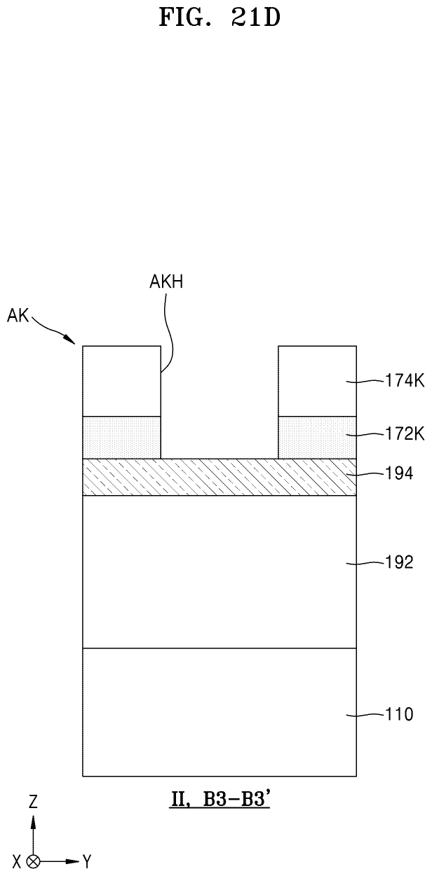

Referring to FIGS. 21A to 21D, the bottom barrier line 182B may be formed by leaving a portion of the bottom barrier layer 182BL disposed below the main conductive line 182M by partially removing the bottom barrier layer 182BL by using the main conductive line 182M as an etching mask.

According to embodiments, as the top surface of the first via conductive layer 162V is covered by the first via skin layer 162S within the first via hole 162H, the upper portion of the first via conductive layer 162V may be prevented from being damaged or oxidized during the process of removing the bottom barrier layer 182BL. Also, as the top surface of the second via conductive layer 164V is covered by the second via skin layer 164S within the second via hole 164H, the upper portion of the second via conductive layer 164V may be prevented from being damaged or oxidized during the process of removing the bottom barrier layer 182BL.

Referring back to FIGS. 1 to 6, the second interlayer insulation layer 176 covering the first wiring line 182 may be formed on the first interlayer insulation layer 174.

Thereafter, an upper via hole 184H may be formed by removing a portion of the second interlayer insulation layer 176, and the upper via 184 may be formed within the upper via hole 184H. The second wiring line 186 electrically connected to the upper via 184 may be formed on the second interlayer insulation layer 176.

The integrated circuit device 100 may be formed through the above-stated operations.

Generally, as the horizontal area of the cell region decreases in a multi-bridge channel type field-effect transistor device, widths of a first via and a first wiring layer also need to decrease. However, for copper wires formed using a conventional damascene method, it is necessary to form an opening in an interlayer insulation layer and then sequentially forming a barrier layer and a copper metal layer in the opening, and thus it is difficult to reduce the width of a wiring layer. To replace the damascene method, a method of forming a first wiring layer using a metal material such as ruthenium, which may be formed by using an etching patterning method is possible. However, the manufacturing cost of the metal material such as ruthenium is expensive and also there is a problem such as increase in electrical resistance due to oxidization of the top surface of a first via by being exposed to an etching atmosphere.

However, according to the embodiments described above, on the first conductive via 162 including the first via conductive layer 162V and the first via skin layer 162S, the first wiring line 182 including the bottom barrier line 182B and the main conductive line 182M may be disposed. The main conductive line 182M may be formed of and/or include a metal material such as tungsten that may be formed by using an etching patterning method and may prevent damage to the first interlayer insulation layer 174 during the process of patterning the bottom barrier line 182B. Also, as the first via skin layer 162S is disposed on the entire top surface of the first via conductive layer 162V, exposure of the first via conductive layer 162V to the etching atmosphere during the etching patterning process may be prevented. Therefore, even when the line width of the first wiring line 182 is reduced, an electrical connection structure with low resistance may be provided, and the integrated circuit device 100 may exhibit excellent electrical characteristics.

According to the inventive concept, on a conductive via including a via conductive layer and a via skin layer, a first wiring line including a bottom barrier line and a main conductive line may be disposed. The main conductive line may be formed of and/or include a metal material such as tungsten that may be formed by using an etching patterning method and may prevent damage to an interlayer insulation layer during the process of patterning the bottom barrier line. Therefore, even when the line width of the first wiring line is reduced, an electrical connection structure with low resistance may be provided, and the integrated circuit device may exhibit excellent electrical characteristics.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate;
a cell transistor disposed on the substrate;
a contact electrically connected to the cell transistor;
a conductive via disposed on the contact and comprising a via conductive layer disposed on a top surface of the contact and a via skin layer covering a top surface of the via conductive layer;
an interlayer insulation layer surrounding a portion of a sidewall of the conductive via; and
a wiring line disposed on the interlayer insulation layer, the wiring line extending in a first horizontal direction, contacting a top surface of the conductive via, and comprising a bottom barrier line and a main conductive line disposed on the bottom barrier line.

2. The integrated circuit device of claim 1, wherein the main conductive line of the wiring line comprises at least one of tungsten, ruthenium, or molybdenum, and
the bottom barrier line of the wiring line comprises molybdenum.

3. The integrated circuit device of claim 1, wherein the via conductive layer of the conductive via comprises at least one of molybdenum, ruthenium, or tungsten, and
the via skin layer of the conductive via comprises tungsten or ruthenium.

4. The integrated circuit device of claim 1, wherein the first interlayer insulation layer has a via hole,
the conductive via is disposed in the via hole, and
a top surface of the via skin layer is disposed at a lower vertical level than a top surface of the interlayer insulation layer.

5. The integrated circuit device of claim 4, wherein a distance between the top surface of the via skin layer and the top surface of the interlayer insulation layer is greater than 0 nm and less than 10 nm.

6. The integrated circuit device of claim 4, wherein a width of an upper portion of the via hole is greater than a width of a lower portion of the via hole, and
a sidewall of the via hole has an inclination angle from about 70 degrees to about 90 degrees with respect to a top surface of the substrate.

7. The integrated circuit device of claim 4, wherein the conductive via has a first width in a second horizontal direction intersecting the first horizontal direction,
a bottom surface of the wiring line has a second width in the second horizontal direction, and
the second width is less than the first width.

8. The integrated circuit device of claim 7, wherein a top surface of the wiring line has a third width in the second horizontal direction,
the third width is less than the second width, and
a sidewall of the wiring line has an inclination angle in the range of 90 degrees to 110 degrees with respect to a top surface of the substrate.

9. The integrated circuit device of claim 1, wherein the bottom barrier line has a thickness in the range of 0.5 nm to 5 nm in a vertical direction that is perpendicular to an upper surface of the substrate.

10. The integrated circuit device of claim 1, wherein the cell transistor comprises:
an active region disposed on the substrate;
a gate line disposed on the active region; and
a source/drain region disposed on both sides of the gate line on the substrate, and
the contact is disposed on the source/drain region.

11. The integrated circuit device of claim 1, wherein the cell transistor comprises:
an active region disposed on the substrate;
a gate line disposed on the active region; and
a source/drain region disposed on opposing sides of the gate line on the substrate, and
the contact is disposed on the gate line.

12. The integrated circuit device of claim 1, wherein the interlayer insulation layer is a first interlayer insulation layer, the integrated circuit device further comprising a second interlayer insulation layer disposed on the first interlayer insulation layer and surrounding sidewalls of the wiring line,
wherein the second interlayer insulation layer is in contact with sidewalls of the main conductive line.

13. The integrated circuit device of claim 1, wherein the interlayer insulation layer is a first interlayer insulation layer and the wiring line is a first wiring line, the integrated circuit device further comprising:
an upper via disposed on the first wiring line and comprising molybdenum;
a second interlayer insulation layer disposed on the first interlayer insulation layer and surrounding sidewalls of the first wiring line and a sidewall of the upper via; and
a second wiring line disposed on the second interlayer insulation layer.

14. An integrated circuit device comprising:
a substrate;
a cell transistor disposed on the substrate;
a contact electrically connected to the cell transistor;
a first interlayer insulation layer disposed on the contact and having a via hole;
a conductive via disposed in the via hole, electrically connected to the contact, and comprising a via conductive layer disposed on a top surface of the contact and a via skin layer covering a top surface of the via conductive layer;
a first wiring line disposed on the first interlayer insulation layer, extending in a first horizontal direction, contacting a top surface of the conductive via, and comprising a bottom barrier line and a main conductive line disposed on the bottom barrier line; and
a second interlayer insulation layer disposed on the first interlayer insulation layer and disposed on sidewalls of the main conductive line and sidewalls of the bottom barrier line.

15. The integrated circuit device of claim 14, wherein the conductive via has a first width in a second horizontal direction intersecting the first horizontal direction,
a bottom surface of the first wiring line has a second width in the second horizontal direction,
the second width is less than the first width,
a top surface of the first wiring line has a third width in the second horizontal direction, and
the third width is less than the second width.

16. The integrated circuit device of claim 14, wherein a top surface of the via skin layer is disposed at a vertical level lower than that of a top surface of the first interlayer insulation layer, and
a distance between the top surface of the via skin layer and the top surface of the first interlayer insulation layer is greater than 0 nm and less than 10 nm.

17. The integrated circuit device of claim 14, wherein a portion of the second interlayer insulation layer is disposed on the top surface of the via skin layer in the via hole.

18. The integrated circuit device of claim 14, wherein the main conductive line of the first wiring line comprises at least one of tungsten, ruthenium, or molybdenum,
the bottom barrier line of the first wiring line comprises molybdenum,
the via conductive layer of the conductive via comprises at least one of molybdenum, ruthenium, or tungsten, and
the via skin layer of the conductive via comprises tungsten or ruthenium.

19. An integrated circuit device comprising:
a substrate;
an active region disposed on the substrate and comprising a plurality of nano-sheets spaced apart from one another in a vertical direction perpendicular to a top surface of the substrate;
a gate line surrounding the plurality of nano-sheets on the substrate and extending in a first horizontal direction;
a source/drain region disposed on opposing sides of the gate line on the substrate;
a contact disposed on the source/drain region;
a conductive via disposed on the first contact and comprising a via conductive layer disposed on a top surface of the first contact and a via skin layer covering a top surface of the via conductive layer;
a first interlayer insulation layer surrounding a sidewall of the conductive via;
a wiring line disposed on the first interlayer insulation layer, extending in a second horizontal line intersecting the first horizontal direction, contacting a top surface of the conductive via, and comprising a bottom barrier line and a main conductive line disposed on the bottom barrier line; and
a second interlayer insulation layer disposed on the first interlayer insulation layer and surrounding sidewalls of the wiring line.

20. The integrated circuit device of claim 19, wherein the main conductive line of the wiring line comprises at least one of tungsten, ruthenium, or molybdenum,
the bottom barrier line of the wiring line comprises molybdenum,
the via conductive layer of the conductive via comprises at least one of molybdenum, ruthenium, or tungsten, and
the via skin layer of the conductive via comprises tungsten or ruthenium.
